(19) United States
(12) Patent Application Publication
(10) Pub. No.: US 2023/0335632 A1
(43) Pub. Date: Oct. 19, 2023

(54) SILICON CARBIDE SEMICONDUCTOR DEVICE

(71) Applicant: SUMITOMO ELECTRIC INDUSTRIES, LTD., Osaka (JP)

(72) Inventor: Kosuke UCHIDA, Osaka (JP)

(21) Appl. No.: 18/043,784

(22) PCT Filed: Sep. 27, 2021
(86) PCT No.: PCT/JP2021/035306

§ 371 Date: Mar. 2, 2023

(30) Foreign Application Priority Data
Nov. 10, 2020 (JP) 2020-187492

(51) Int. Cl. H01L 29/78; H01L 29/872; H01L 29/47; H01L 29/06; H01L 29/16

(52) U.S. Cl. CPC H01L 29/7806; H01L 29/872; H01L 29/47; H01L 29/0623; H01L 29/1608; H01L 29/7811; H01L 29/7813

(57) ABSTRACT

A silicon carbide semiconductor device includes a silicon carbide substrate having a first main surface and a second main surface. The silicon carbide substrate includes an element region including transistors; and a termination region surrounding the element region, the termination region including a first Schottky barrier diode. The silicon carbide substrate includes a first semiconductor region having a first conductivity type; a first surface located between the first main surface and the second main surface; and a second semiconductor region provided on the first surface, the second semiconductor region having a second conductivity type different from the first conductivity type. The second semiconductor region includes a first embedding region provided in the termination region, a first opening being formed in the first embedding region. The first Schottky barrier diode includes a first Schottky electrode provided on the first main surface, the first Schottky electrode overlapping the first opening.

### TECHNICAL FIELD

The present invention relates to a silicon carbide semiconductor device.

### BACKGROUND ART

This application claims priority to Japanese Patent Application No. 2020-187492, filed on Nov. 10, 2020, the entire contents of which are incorporated herein by reference.

As one of silicon carbide semiconductor devices, a silicon carbide semiconductor device is disclosed in which a transistor is provided in an element region and a Schottky barrier diode is provided in a guard ring region (for example, Patent Document 1).

### CITATION LIST

### [Patent Document]

[Patent Document 1] Japanese Unexamined Patent Application Publication No. 2014-170778

### SUMMARY

A silicon carbide semiconductor device according to the present disclosure includes a silicon carbide substrate having a first main surface and a second main surface opposite the first main surface. When viewed in a plan view from a direction perpendicular to the first main surface, the silicon carbide substrate includes an element region including a plurality of transistors; and a termination region surrounding the element region, the termination region including a first Schottky barrier diode. The silicon carbide substrate forms the second main surface, the silicon carbide substrate including a first semiconductor region having a first conductivity type; a first surface located between the first main surface and the second main surface; and a second semiconductor region provided on the first surface, the second semiconductor region having a second conductivity type different from the first conductivity type. The second semiconductor region includes a first embedding region provided in the termination region, a first opening being formed in the first embedding region. The first Schottky barrier diode includes a first Schottky electrode provided on the first main surface, the first Schottky electrode overlapping the first opening when viewed in the plan view from the direction perpendicular to the first main surface.

### BRIEF DESCRIPTION OF DRAWINGS

FIG. 1 is a schematic diagram illustrating the layout of a MOSFET according to an embodiment.

FIG. 2 is an enlarged view of a region A in FIG. 1.

FIG. 3 is an enlarged view of a region B in FIG. 1.

FIG. 4 is a cross-sectional view (part 1) of the configuration of a silicon carbide semiconductor device according to the embodiment.

FIG. 5 is a cross-sectional view (part 2) of the configuration of the silicon carbide semiconductor device according to the embodiment.

FIG. 6 is a cross-sectional view (part 3) of the configuration of the silicon carbide semiconductor device according to the embodiment.

FIG. 7 is a cross-sectional view (part 4) of the configuration of the silicon carbide semiconductor device according to the embodiment.

FIG. 8 is a diagram illustrating the configuration of a first surface in an element region.

FIG. 9 is a diagram illustrating the configuration of the first surface in a termination region.

FIG. 10 is a cross-sectional view (part 1) of the silicon carbide semiconductor device according to the embodiment, the cross-sectional view being described for a method for manufacturing the silicon carbide semiconductor device.

FIG. 11 is a cross-sectional view (part 2) of the silicon carbide semiconductor device according to the embodiment, the cross-sectional view being described for the method for manufacturing the silicon carbide semiconductor device.

FIG. 12 is a cross-sectional view (part 3) of the silicon carbide semiconductor device according to the embodiment, the cross-sectional view being described for the method for manufacturing the silicon carbide semiconductor device.

FIG. 13 is a cross-sectional view (part 4) of the silicon carbide semiconductor device according to the embodiment, the cross-sectional view being described for the method for manufacturing the silicon carbide semiconductor device.

FIG. 14 is a cross-sectional view (part 5) of the silicon carbide semiconductor device according to the embodiment, the cross-sectional view being described for the method for manufacturing the silicon carbide semiconductor device.

FIG. 15 is a cross-sectional view (part 6) of the silicon carbide semiconductor device according to the embodiment, the cross-sectional view being described for the method for manufacturing the silicon carbide semiconductor device.

FIG. 16 is a cross-sectional view (part 7) of the silicon carbide semiconductor device according to the embodiment, the cross-sectional view being described for the method for manufacturing the silicon carbide semiconductor device.

FIG. 17 is a cross-sectional view (part 8) of the silicon carbide semiconductor device according to the embodiment, the cross-sectional view being described for the method for manufacturing the silicon carbide semiconductor device.

FIG. 18 is a cross-sectional view (part 9) of the silicon carbide semiconductor device according to the embodiment, the cross-sectional view being described for the method for manufacturing the silicon carbide semiconductor device.

FIG. 19 is a cross-sectional view (part 10) of the silicon carbide semiconductor device according to the embodiment, the cross-sectional view being described for the method for manufacturing the silicon carbide semiconductor device.

FIG. 20 is a cross-sectional view (part 11) of the silicon carbide semiconductor device according to the embodiment, the cross-sectional view being described for the method for manufacturing the silicon carbide semiconductor device.

FIG. 21 is a cross-sectional view (part 12) of the silicon carbide semiconductor device according to the embodiment, the cross-sectional view being described for the method for manufacturing the silicon carbide semiconductor device.

FIG. 22 is a cross-sectional view (part 13) of the silicon carbide semiconductor device according to the embodiment, the cross-sectional view being described for the method for manufacturing the silicon carbide semiconductor device.

FIG. 23 is a cross-sectional view (part 14) of the silicon carbide semiconductor device according to the embodiment, the cross-sectional view being described for the method for manufacturing the silicon carbide semiconductor device.

FIG. 24 is a cross-sectional view (part 15) of the silicon carbide semiconductor device according to the embodiment, the cross-sectional view being described for the method for manufacturing the silicon carbide semiconductor device.

FIG. 25 is a cross-sectional view (part 16) of the silicon carbide semiconductor device according to the embodiment, the cross-sectional view being described for the method for manufacturing the silicon carbide semiconductor device.

FIG. 26 is a cross-sectional view (part 17) of the silicon carbide semiconductor device according to the embodiment, the cross-sectional view being described for the method for manufacturing the silicon carbide semiconductor device.

FIG. 27 is a cross-sectional view (part 18) of the silicon carbide semiconductor device according to the embodiment, the cross-sectional view being described for the method for manufacturing the silicon carbide semiconductor device.

FIG. 28 is a cross-sectional view (part 19) of the silicon carbide semiconductor device according to the embodiment, the cross-sectional view being described for the method for manufacturing the silicon carbide semiconductor device.

FIG. 29 is a cross-sectional view (part 20) of the silicon carbide semiconductor device according to the embodiment, the cross-sectional view being described for the method for manufacturing the silicon carbide semiconductor device.

FIG. 30 is a cross-sectional view (part 21) of the silicon carbide semiconductor device according to the embodiment, the cross-sectional view being described for the method for manufacturing the silicon carbide semiconductor device.

FIG. 31 is a cross-sectional view (part 22) of the silicon carbide semiconductor device according to the embodiment, the cross-sectional view being described for the method for manufacturing the silicon carbide semiconductor device.

FIG. 32 is a cross-sectional view (part 23) of the silicon carbide semiconductor device according to the embodiment, the cross-sectional view being described for the method for manufacturing the silicon carbide semiconductor device.

FIG. 33 is a cross-sectional view (part 24) of the silicon carbide semiconductor device according to the embodiment, the cross-sectional view being described for the method for manufacturing the silicon carbide semiconductor device.

FIG. 34 is a cross-sectional view (part 25) of the silicon carbide semiconductor device according to the embodiment, the cross-sectional view being described for the method for manufacturing the silicon carbide semiconductor device.

FIG. 35 is a cross-sectional view (part 26) of the silicon carbide semiconductor device according to the embodiment, the cross-sectional view being described for the method for manufacturing the silicon carbide semiconductor device.

FIG. 36 is a cross-sectional view (part 27) of the silicon carbide semiconductor device according to the embodiment, the cross-sectional view being described for the method for manufacturing the silicon carbide semiconductor device.

FIG. 37 is a cross-sectional view (part 28) of the silicon carbide semiconductor device according to the embodiment, the cross-sectional view being described for the method for manufacturing the silicon carbide semiconductor device.

FIG. 38 is a cross-sectional view of an example of the silicon carbide semiconductor device including a temperature sensing structure.

FIG. 39 is a cross-sectional view of another example of the silicon carbide semiconductor device including the temperature sensing structure.

### DESCRIPTION OF EMBODIMENTS

### [Problems to be Solved by the Present Disclosure]

In a conventional silicon carbide semiconductor device, a diode with a parasitic p-n junction in the silicon carbide semiconductor device operates before a Schottky barrier diode operates, and thus a property is reduced.

An object of the present disclosure is to provide a silicon carbide semiconductor device capable of suppressing reductions in a property in accordance with operation of a p-n junction diode.

### [Effect of the Present Disclosure]

According to the present disclosure, reductions in a property in accordance with operation of a p-n junction diode can be suppressed.

Embodiments are described below.

### [Description of Embodiments of the Present Disclosure]

Embodiments of the present disclosure will be listed and described as follows. In the following description, the same or corresponding components are denoted by the same numerals, and description thereof will not be provided repeatedly. In a crystallographic description in the specification, an individual orientation is represented by [ ], an aggregate orientation is represented by < >, an individual plane is represented by ( ) and an aggregate plane is represented by { }. A negative crystallographic index is generally expressed by placing “-” (bar) on top of a number, but in this specification, a negative sign is placed before the number.

[1] A silicon carbide semiconductor device according to one aspect of the present disclosure includes a silicon carbide substrate having a first main surface and a second main surface opposite the first main surface. When viewed in a plan view from a direction perpendicular to the first main surface, the silicon carbide substrate includes an element region including a plurality of transistors; and a termination region surrounding the element region, the termination region including a first Schottky barrier diode. The silicon carbide substrate forms the second main surface, the silicon carbide substrate including a first semiconductor region having a first conductivity type; a first surface located between the first main surface and the second main surface; and a second semiconductor region provided on the first surface, the second semiconductor region having a second conductivity type different from the first conductivity type. The second semiconductor region includes a first embedding region provided in the termination region, a first opening being formed in the first embedding region. The first Schottky barrier diode includes a first Schottky electrode provided on the first main surface, the first Schottky electrode overlapping the first opening when viewed in the plan view from the direction perpendicular to the first main surface.

A first Schottky electrode is provided so as to overlap a first opening that is formed in a first embedding region when viewed in a plan view from a direction perpendicular to a first main surface. With this arrangement, upon a first Schottky barrier diode operating, the current flows through the first opening. If the first opening is not formed, the current flows so as to bypass the first embedding region. In contrast, with the first opening being formed, a current path can be shortened. Reductions in the resistance of the current path allow the first Schottky barrier diode to easily start up. Thus, the first Schottky barrier diode operates more quickly than a diode with a parasitic p-n junction in the silicon carbide semiconductor device. Therefore, reductions in a property in accordance with the operation of the p-n junction diode can be mitigated.

[2] In [1], a first opening has a rectangular planar shape, and a second semiconductor region includes a plurality of electric-field relaxing regions provided in an element region. A distance between adjacent electric-field relaxing regions may be greater than a length of a shortest side of the first opening when viewed in the plan view from the direction perpendicular to the first main surface. In this case, electric field concentration in a first embedding region is reduced, and thus reductions in a withstand voltage of a termination region can be mitigated.

[3] In [1] or [2], an element region includes an active region in which a plurality of transistors are arranged, and includes a non-active region provided around the active region, the non-active region including a plurality of second Schottky barrier diodes. A second semiconductor region includes a second embedding region provided in the non-active region, a second opening being formed in the second embedding region. Each of the second Schottky barrier diodes may include a second Schottky electrode provided on a first main surface, the second Schottky electrode overlapping the second opening when viewed in a plan view from a direction perpendicular to a first main surface. In this case, reductions in a property in accordance with operation of a p-n junction diode in a non-active region can be mitigated.

[4] In [3], a silicon carbide semiconductor device further includes a gate pad to which gate electrodes of a plurality of transistors are coupled, the gate pad being situated above a first main surface. A plurality of second Schottky barrier diodes may be arranged along the gate pad when viewed in a plan view from a direction perpendicular to the first main surface. In this case, reductions in a property in accordance with operation of a p-n junction diode that includes a second embedding region below a gate pad can be mitigated.

[5] In [3] or [4], a silicon carbide semiconductor device further includes a gate runner to which gate electrodes of a plurality of transistors are coupled, the gate runner being situated above a first main surface. A plurality of second Schottky barrier diodes may be arranged along the gate runner when viewed in a plan view from a direction perpendicular to a first main surface. In this case, reductions in a property in accordance with operation of a p-n junction diode that includes a second embedding region below a gate runner can be mitigated.

[6] In [3] to [5], the silicon carbide semiconductor device further includes a temperature sensing structure provided in the non-active region. A plurality of second Schottky barrier diodes may be arranged along the temperature sensing structure when viewed in a plan view from a direction perpendicular to a first main surface. In this case, reductions in a property in accordance with operation of a p-n junction diode that includes a second embedding region below a temperature sensing structure can be mitigated.

In [3] to [6], a turn-on voltage of each of a plurality of second Schottky barrier diodes may be lower than a turn-on voltage of a diode that includes a p-n junction between a second embedding region and a first semiconductor region. This is because reductions in a property in accordance with operation of a diode with a p-n junction diode is mitigated.

### [Embodiments of the Present Disclosure]

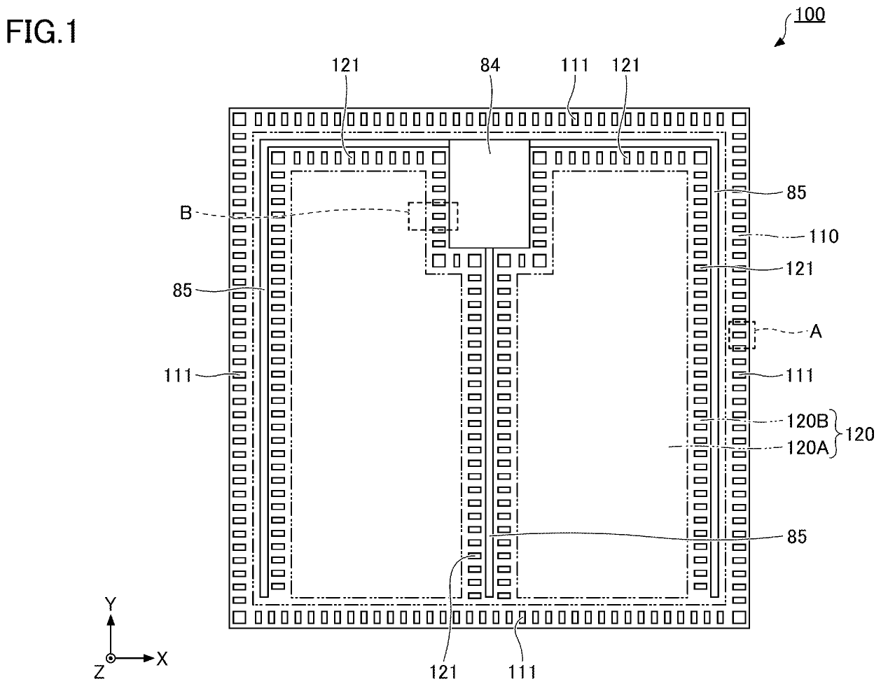

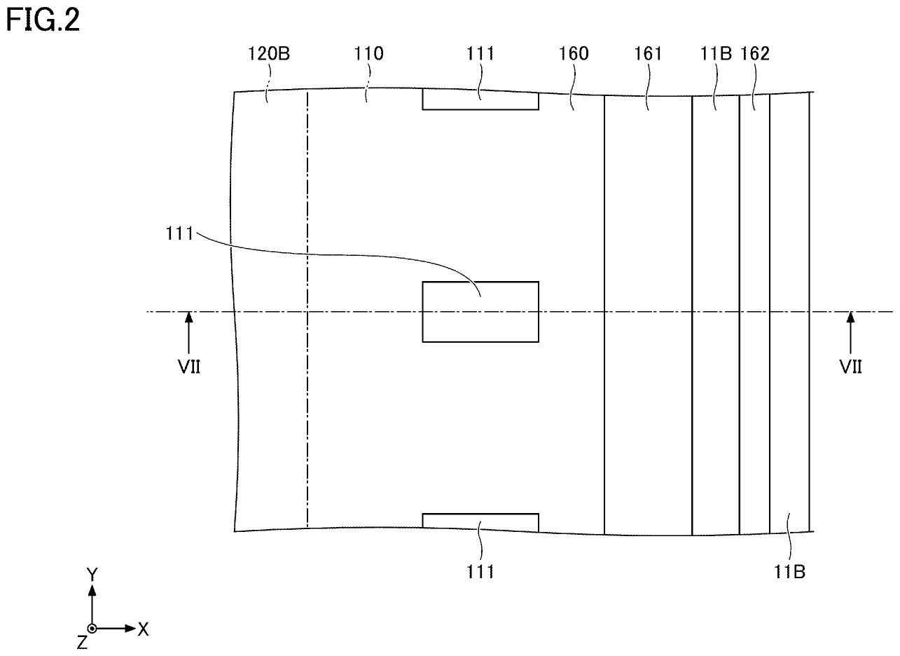

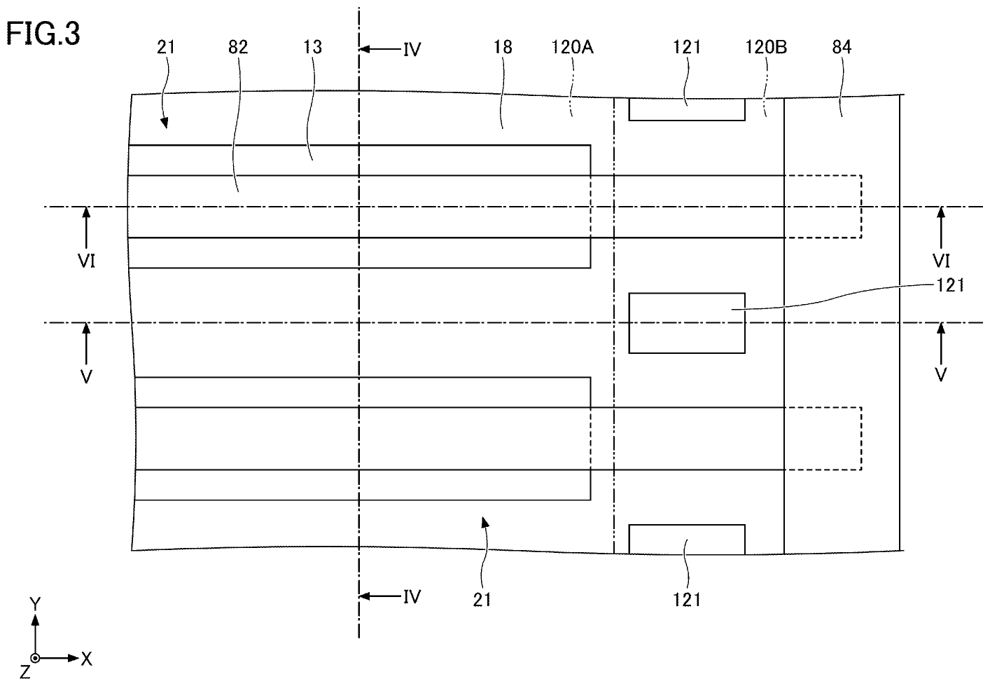

One or more embodiments of the present disclosure relate to a so-called vertical MOSFET (silicon carbide semiconductor device). FIG. 1 is a schematic diagram illustrating the layout of the MOSFET according to the embodiment. FIG. 2 is an enlarged view of a region A in FIG. 1. FIG. 3 is an enlarged view of a region B in FIG. 1.

The schematic layout of a MOSFET 100 according to the present embodiment will be described as follows. As illustrated in FIG. 1, the MOSFET 100 has a rectangular planar shape with two sides parallel to an X-direction and two sides parallel to a Y-direction. The MOSFET 100 includes a device region 120 and a termination region 110. The termination region 110 surrounds the element region 120 in a plan view.

A gate pad 84 and gate runners 85 that are coupled to the gate pad 84 are provided in the element region 120. The gate pad 84 and the gate runner 85 are each made of a metal having low electrical resistance, such as aluminum or an aluminum alloy. The gate pad 84 is configured such that a gate voltage is applied from the outside.

The gate pad 84 is disposed at a middle portion in the X-direction and in proximity to one side parallel to the X-direction. For example, three gate runners 85 are provided, and one of these gate runners extends in the −Y direction from the gate pad 84 to a location proximal to the boundary between the element region 120 and the terminal region 110. Another gate runner extends from the gate pad 84 in the +X direction, bends in the -Y direction at a location proximal to the boundary between the element region 120 and the terminal region 110, and then extends in the −Y direction to a location proximal to the boundary between the element region 120 and the terminal region 110. The third extends in the −X direction from the gate pad 84, bends in the −Y direction at a location proximal to the boundary between the element region 120 and the termination region 110, and then extends in the −Y direction to a location proximal to the boundary between the element region 120 and the termination region 110.

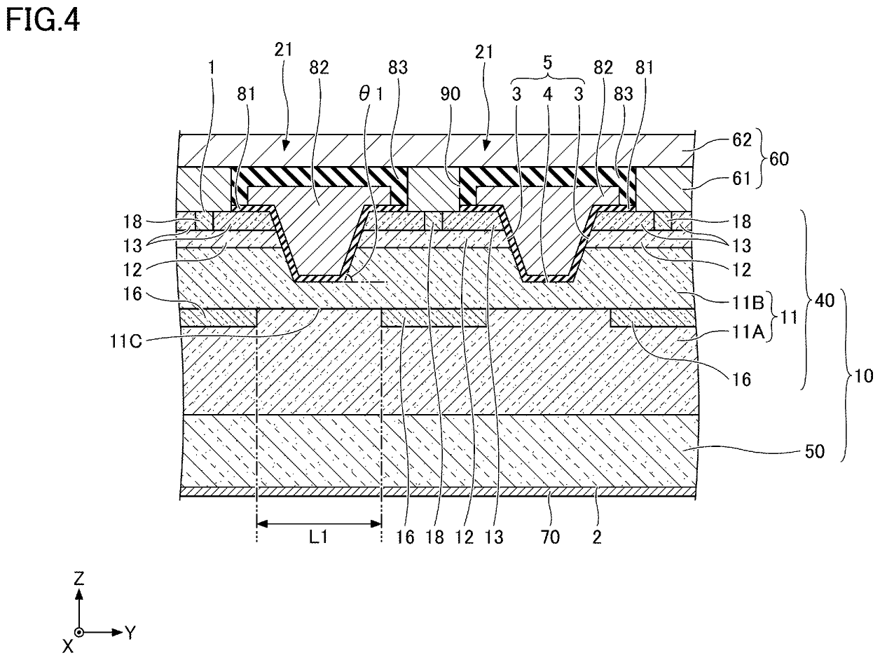

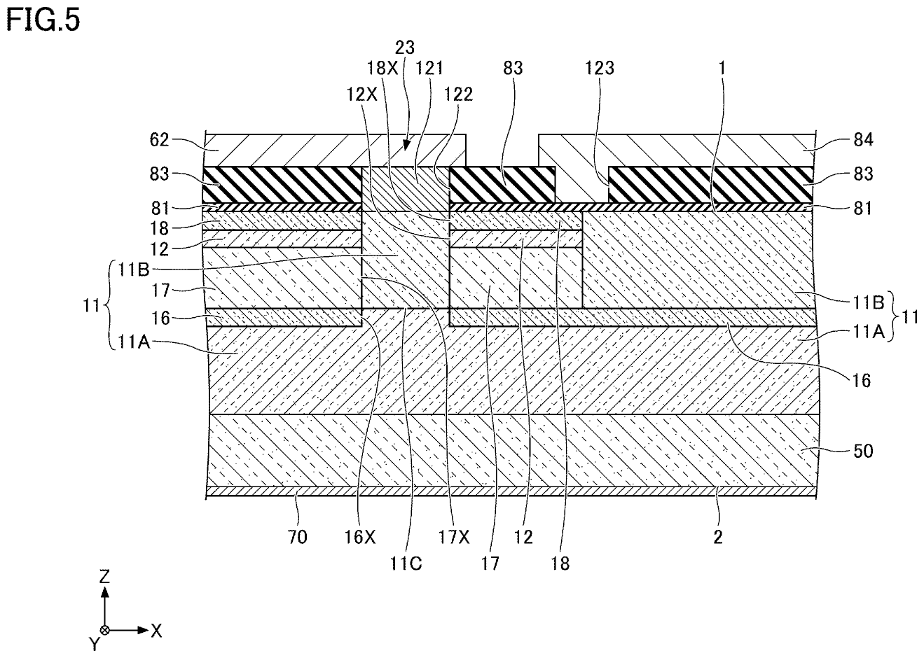

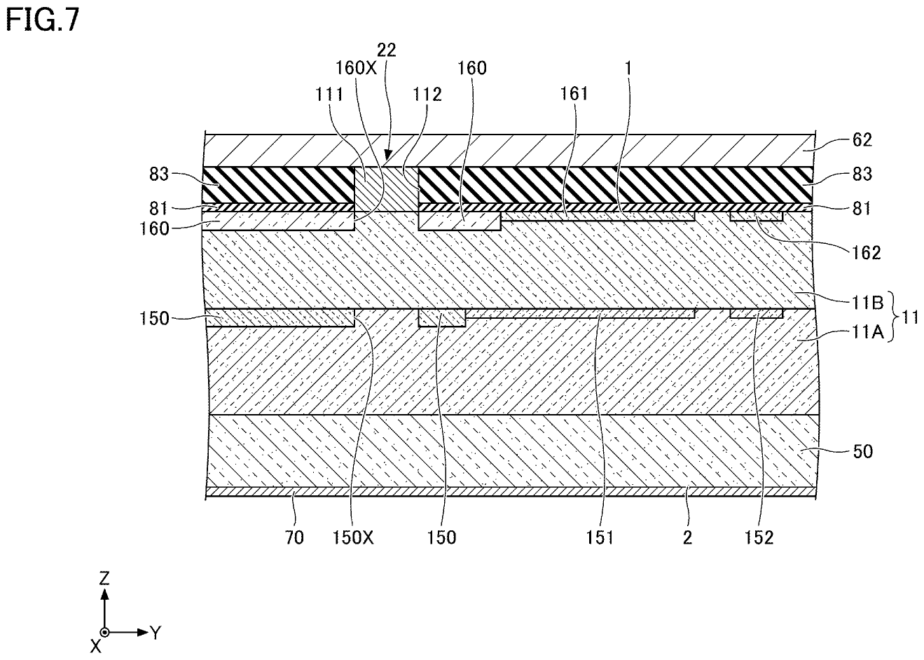

Although details will be described later, a plurality of transistors 21 (see FIGS. 3 and 4) each including a gate electrode 82 that is coupled to a corresponding gate runner 85 are provided in the element region 120. Also, a plurality of first Schottky barrier diodes 22 (see FIG. 7) each of which is coupled to a corresponding transistor 21 are provided in the termination region 110, and a plurality of second Schottky barrier diodes 23 (see FIG. 5) each of which is coupled to a corresponding transistor 21 are provided in the element region 120.

As illustrated in FIGS. 1 and 2, Schottky electrodes 111 in the respective first Schottky barrier diodes 22 are provided in the termination region 110. The Schottky electrodes 111 are arranged along an outer periphery of the MOSFET 100, when viewed in a plan view from a Z-direction perpendicular to a first main surface 1. The Schottky electrode 111 is an example of a first Schottky electrode.

As illustrated in FIGS. 1 and 3, the device region 120 includes an active region 120A in which the transistors 21 are arranged, and includes a non-active region 120B including second Schottky barrier diodes 23. The gate pad 84, the gate runners 85, and the second Schottky barrier diodes 23 are provided in the non-active region 120B. Each of the second

Schottky barrier diodes 23 has a Schottky electrode 121. The Schottky electrodes 121 are arranged along the gate pad 84 and the gate runners 85, when viewed in a plan view from the Z-direction. Given Schottky electrodes 121 may intermittently surround the gate pad 84. The Schottky electrodes 121 do not need to surround the entire perimeter of the gate pad 84, and may be arranged along three sides of the gate pad 84 of which the planar shape is a rectangle, for example. The Schottky electrode 121 is an example of a second Schottky electrode.

Each of the Schottky electrodes 111 and 121 is preferably made of a metal having a work function less than 4.33 eV, which is the work function of Ti.

Each of the Schottky electrodes 111 and 121 is preferably made of metal having a work function greater than 3.7 eV, which corresponds to an electrical affinity of silicon carbide. Each of the Schottky electrodes 111 and 121 preferably has a melting point of 1000° C. or higher from the viewpoint of stability at high temperatures. The electronegativity of the atom included in each of the Schottky electrodes 111 and 121 is preferably less than the electronegativity of the atom included in silicon carbide, that is, the electronegativity of each of Si and C. Examples of the metal that satisfies the above conditions include Hf, Zr, Ta, Mn, Nb, and V. Each of the Schottky electrodes 111 and 121 may be made of any single one of these metal elements, or may be made of an alloy including two or more of these metal elements.

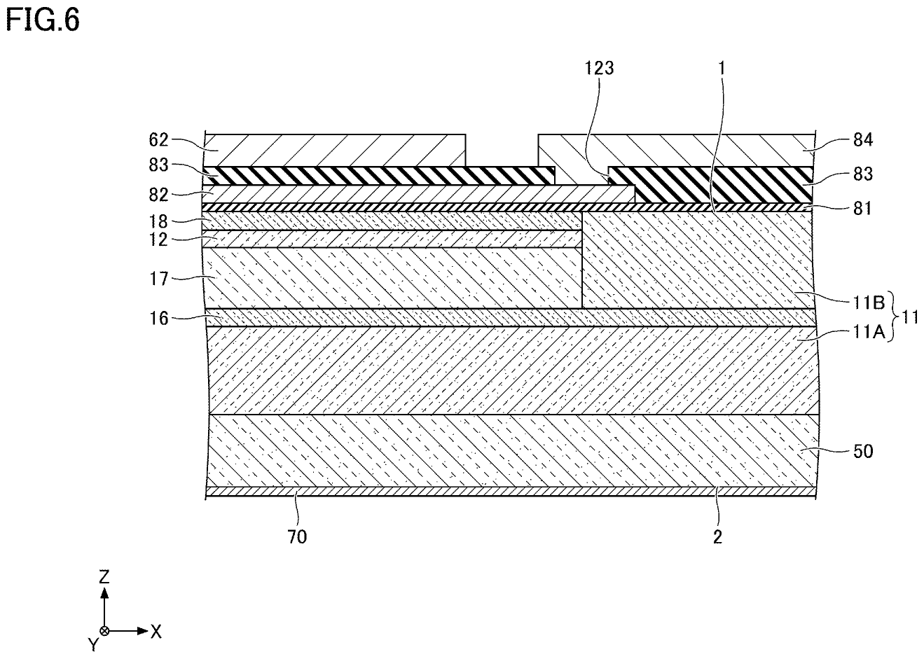

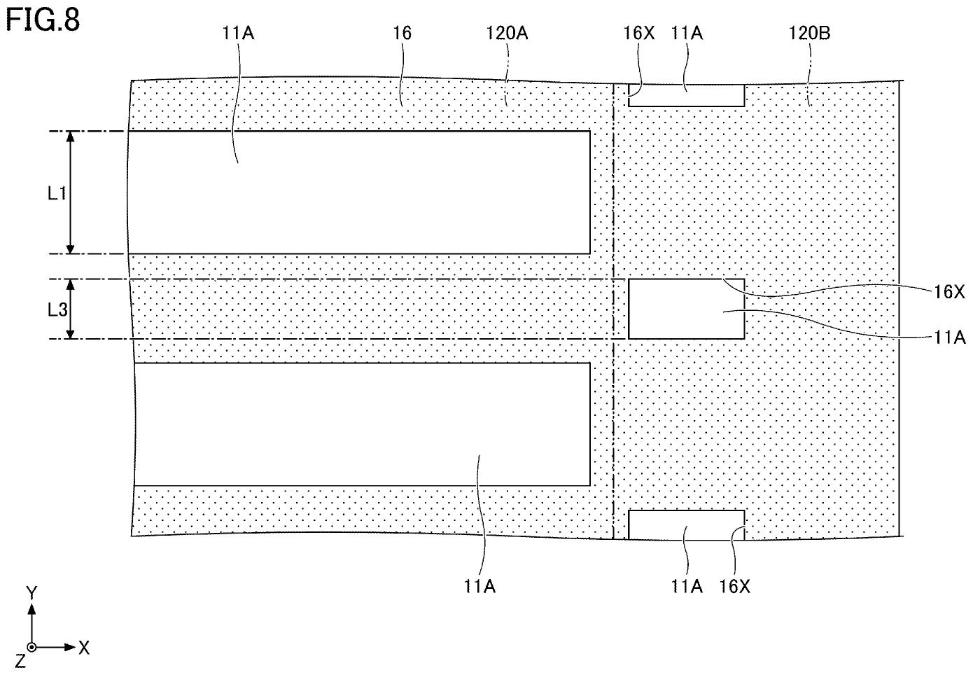

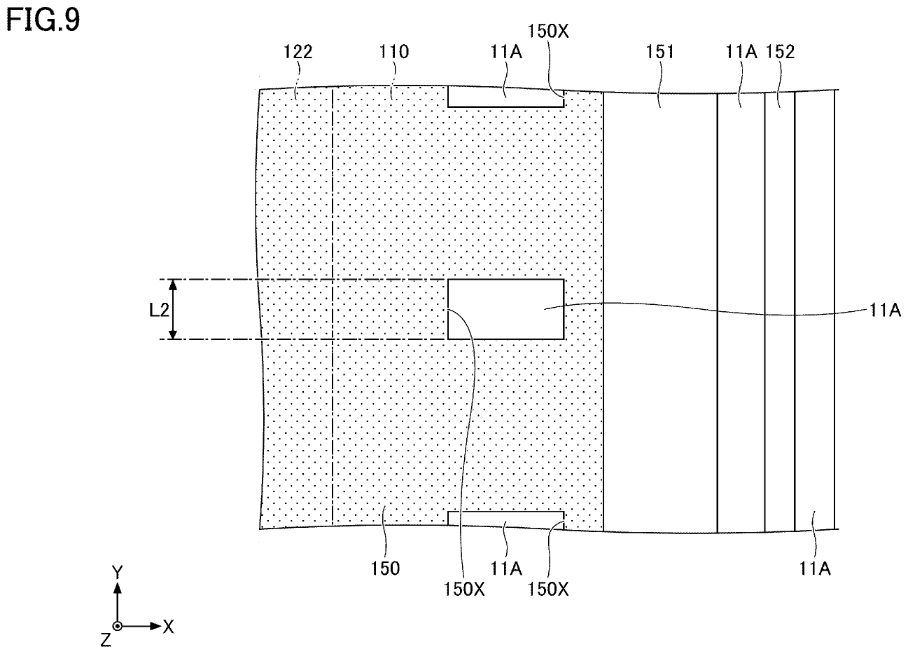

The cross section of the MOSFET 100 according to the present embodiment will be described below in detail. FIGS. 4 to 7 are cross-sectional views of the configuration of the silicon carbide semiconductor device according to the embodiment. FIG. 4 is a view corresponding to the cross-sectional view taken along line IV-IV in FIG. 3. FIG. 5 is a view corresponding to the cross-sectional view taken along line V-V in FIG. 3. FIG. 6 is a view corresponding to the cross-sectional view taken along line VI-VI in FIG. 3. FIG. 7 is a view corresponding to the cross-sectional view taken along line VII-VII in FIG. 2. FIG. 8 is a diagram illustrating the configuration of a first surface in the element region. FIG. 9 is a diagram illustrating the configuration of the first surface in the termination region.

As illustrated in FIGS. 4 to 7, the MOSFET 100 according to the present embodiment mainly includes a silicon carbide substrate 10, a gate insulating film 81, the gate electrodes 82, an interlayer insulating film 83, a source electrode 60, a drain electrode 70, the Schottky electrodes 111, and the Schottky electrodes 121. The silicon carbide substrate 10 includes a silicon carbide single-crystal substrate 50 and a silicon carbide epitaxial layer 40 on the silicon carbide single-crystal substrate 50. The silicon carbide substrate 10 has a first main surface 1 and a second main surface 2 opposite to the first main surface 1. The silicon carbide epitaxial layer 40 forms the first main surface 1, and the silicon carbide single-crystal substrate 50 forms the second main surface 2. Each of the silicon carbide single-crystal substrate 50 and the silicon carbide epitaxial layer 40 is formed, for example, by hexagonal silicon carbide of 4H polytype. The silicon carbide single-crystal substrate 50 includes n-type impurities such as nitrogen (N), and thus is an re-type (first conductivity type).

The first main surface 1 is a {0001} plane or a plane in which the {0001} plane is inclined by an off angle of 8° or less in an off direction. Preferably, the first main surface 1 is the (000-1) plane or a plane in which the (000-1) plane is inclined by an off angle of 8° or less in the off direction. The off direction may be, for example, a <11-20> direction or a <1-100> direction. The off angle may be, for example, 1° or more, or be 2° or more. The off angle may be 6° or less, or may be 4° or less.

As illustrated in FIGS. 3 and 4, the silicon carbide epitaxial layer 40 mainly includes a drift region 11, a body region 12, a source region 13, an electric-field relaxing region 16, and a contact region 18.

The drift region 11 is the n-type by being doped with a donor such as nitrogen or phosphorus (P). The drift region 11 includes a first region 11A and a second region 11B. A first surface 11C is provided between the first region 11A and the second region 11B. The second region 11B is provided on and above the first region 11A. It is preferable that doping of the donor into the drift region 11 is carried out by impurities added during epitaxial growth of the drift region 11, without using ion implantation. A donor concentration of the drift region 11 is preferably less than a donor concentration of the silicon carbide single-crystal substrate 50. The donor concentration of each of the first region 11A and the second region 11B is preferably greater than or equal to 1×10¹⁵ cm⁻³ and less than or equal to 5×10¹⁶ cm⁻³, and is, for example, about 8×10¹⁵ cm⁻³. The donor concentration of the first region 11A may be different from that of the second region 11B. The drift region 11 is an example of a first semiconductor region.

The body region 12 is provided on the drift region 11. The body region 12 is a p-type (second conductivity type) by being doped with an acceptor such as aluminum (Al). An acceptor concentration of the body region 12 is, for example, about 1×10¹⁸ cm⁻³.

The source region 13 is provided on the body region 12 so as to be separated from the drift region 11 by the body region 12. The source region 13 is the re-type by being doped with a donor such as nitrogen or phosphorus. The source region 13 forms the first main surface 1. A donor concentration of the source region 13 is, for example, about 1×10¹⁹ cm⁻³.

The contact region 18 is the p-type by being doped with an acceptor such as aluminum. The contact region 18 forms the first main surface 1. The contact region 18 passes through the source region 13 and is in contact with the body region 12. An acceptor concentration of the contact region 18 is greater than or equal to 1×10¹⁸ cm⁻³ and less than or equal to 1×10²⁰ cm⁻³, for example.

In the active region 120A, a plurality of gate trenches 5 are provided at the first main surface 1. Each of the gate trenches 5 extends, for example, in the X-direction parallel to the first main surface 1, and the gate trenches 5 are arranged in the Y-direction, parallel to the first main surface 1, and perpendicular to the X-direction. Each gate trench 5 has a bottom surface 4 that is formed by the drift region 11. The gate trench 5 passes through the contact region 18, the source region 13, and the body region 12, and has a side surface 3 that is coupled to the bottom surface 4. The bottom surface 4 is, for example, a plane parallel to the second main surface 2. An angle θ1 of the side surface 3 with respect to a plane that includes the bottom surface 4 is, for example, greater than or equal to 45° and less than or equal to 65°. The angle θ1 may be, for example, 50° or more. The angle θ1 may be, for example, 60° or less. The side surface 3 preferably has a {0-33-8} plane. The {0-33-8} plane is a crystal plane that allows for excellent mobility.

The electric-field relaxing region 16 includes a p-type impurity such as Al, and has p conductivity. The electric-field relaxing region 16 is provided on the surface of the first region 11A, and forms the first surface 11C. The electric-field relaxing region 16 is provided between adjacent gate trenches 5 in the Y-direction, when viewed in the plan view from the Z-direction. An acceptor concentration of the electric-field relaxing region 16 is, for example, greater than or equal to 5×10¹⁷ cm⁻³ and less than or equal to 5×10¹⁸ cm⁻³. The electric-field relaxing region 16 is a portion of a second semiconductor region.

The gate insulating film 81 is, for example, an oxide film. The gate insulating film 81 is made of, for example, a material including silicon dioxide. The gate insulating film 81 is in contact with the side surfaces 3 and the bottom surfaces 4. The gate insulating film 81 contacts the drift region 11 at each bottom surface 4. The gate insulating film 81 contacts, at each side surface 3, the contact region 18, the source region 13, the body region 12, and the drift region 11. The gate insulating film 81 may contact the source region 13 at the first main surface 1.

The gate electrodes 82 are provided on the gate insulating film 81. The gate electrode 82 is made of, for example, polysilicon (poly-Si) including conductive impurities. Each of the gate electrodes 82 is disposed within a corresponding gate trench 5. The gate electrode 82 extends into the non-active region 120B and is coupled to a corresponding gate pad 84 or a corresponding gate runner 85.

The interlayer insulating film 83 is provided in contact with the gate electrodes 82 and the gate insulating film 81. The interlayer insulating film 83 is made of, for example, a material including silicon dioxide. The interlayer insulating film 83 electrically insulates the gate electrodes 82 from the source electrode 60.

Contact holes 90 are formed in the interlayer insulating film 83 and the gate insulating film 81 to be arranged at regular intervals in the Y-direction. The contact holes 90 are provided such that the gate trenches 5 are each located between adjacent contact holes 90 in the Y-direction. Each contact hole 90 extends in the X-direction. Each of the source region 13 and the contact region 18 is exposed from the interlayer insulating film 83 and the gate insulating film 81, through the contact holes 90.

The source electrode 60 contacts the first main surface 1. The source electrode 60 includes a contact electrode 61 provided in the contact holes 90 and includes a source line 62. The contact electrode 61 contacts the source region 13 and the contact region 18, at the first main surface 1. The contact electrode 61 is made of, for example, a material including nickel silicide (NiSi). The contact electrode 61 may be made of a material including titanium (Ti), Al, and Si. The contact electrode 61 is in ohmic contact with the source region 13 and the contact region 18. The source line 62 is made of, for example, a material including Al.

The drain electrode 70 contacts the second main surface 2. The drain electrode 70 contacts the silicon carbide single-crystal substrate 50 at the second main surface 2. The drain electrode 70 is electrically coupled to the drift region 11. The drain electrode 70 is made of, for example, a material including NiSi. The drain electrode 70 may be made of a material including Ti, Al, and Si. The drain electrode 70 is in ohmic contact with the silicon carbide single-crystal substrate 50.

As illustrated in FIGS. 3, 5, and 6, in the non-active region 120B, the Schottky electrodes 121 are each provided between adjacent given gate electrodes 82 in the Y-direction, when viewed in the plan view from the Z-direction. The Schottky electrodes 121 are each disposed in the X-direction between the active region 120A and either a corresponding gate pad 84 or a corresponding gate runner 85.

The contact holes 122 used for the respective Schottky electrodes 121 are formed in the interlayer insulating film 83 and the gate insulating film 81.

In addition, in order to overlap each contact hole 122 when viewed in the plan view from the Z-direction, a corresponding opening 18X is formed in the contact region 18 and, a corresponding opening 12X is formed in the body region 12. The second region 11B is exposed from the interlayer insulating film 83 and the gate insulating film 81, through the contact holes 122. The Schottky electrodes 121 are provided in the respective contact holes 122, and each Schottky electrode 121 provides a Schottky barrier in the second region 11B. The Schottky electrodes 121 are coupled to the source line 62. As illustrated in FIGS. 5 and 8, openings 16X are formed in the electric-field relaxing region 16 in the non-active region 120B. Each of the openings 16X has, for example, a rectangular planar shape. The first region 11A is exposed through the openings 16X. When viewed in the plan view from the Z-direction, a distance L1 between adjacent electric-field relaxing regions 16 may be greater than a length L3 of the shortest side of the opening 16X. As illustrated in FIGS. 5 and 6, a connection region 17 that includes a p-type impurity such as Al and has p conductivity may be provided between the body region 12 and the electric-field relaxing region 16. In this case, each opening 17X is formed in the connection region 17 so as to overlap a corresponding contact hole 122, when viewed in the plan view from the Z-direction. The second region 11B and the first region 11A directly contact each other at the first surface 11C, directly beneath each Schottky electrode 121. A portion of the electric-field relaxing region 16 in the non-active region 120B is an example of a second embedding region and is a portion of a second semiconductor region. The opening 16X is an example of a second opening.

A contact hole 123 used for the gate pad 84 is formed in the interlayer insulating film 83. The gate pad 84 is coupled to a portion of the gate electrodes 82 through the contact holes 123. Contact holes (not illustrated) used for the gate runners 85 are also formed in the interlayer insulating film 83, and each gate runner 85 is coupled to a portion of the gate electrodes 82 through the contact holes. Each gate electrode 82 is coupled to at least one of the gate pad 84 or a corresponding gate runner 85.

As illustrated in FIGS. 2, 7, and 9, in the termination region 110, contact holes 112 used for the respective Schottky electrodes 111 are formed in the interlayer insulating film 83 and the gate insulating film 81. The second region 11B is exposed from the interlayer insulating film 83 and the gate insulating film 81, through the contact holes 112.

The Schottky electrodes 111 are provided in the respective contact holes 112, and each Schottky electrode 111 provides a Schottky barrier in the second region 11B. The Schottky electrodes 111 are coupled to the source line 62.

In the termination region 110, an embedding region 150, an embedding junction termination extension (JTE) region 151, and an embedding guard ring region 152 are provided at the surface of the first region 11A. Each of the embedding region 150, the embedding JTE region 151, and the embedding guard ring region 152 includes a p-type impurity such as Al, and has the p conductivity. The acceptor concentration of the embedding region 150 is, for example, greater than or equal to 5×10¹⁷ cm⁻³ and less than or equal to 5×10¹⁸ cm⁻³. The acceptor concentration of the embedding JTE region 151 is, for example, greater than or equal to 5×10¹⁶ cm⁻³ and less than or equal to 1×10¹² cm⁻³. The acceptor concentration of the embedding guard ring region 152 is greater than or equal to 5×10¹⁶ cm⁻³ and less than or equal to 1×10¹⁸ cm⁻³, for example. The embedding region 150 is an example of a first embedding region and is a portion of a second semiconductor region.

Openings 150X are each formed in the embedding region 150 so as to overlap a corresponding contact hole 112 when viewed in the plan view from the Z-direction. When viewed in the plan view from the Z-direction, the distance L1 between adjacent electric-field relaxing regions 16 may be greater than a length L2 of the shortest side of the opening 150X. The first region 11A is exposed through the openings 150X. The embedding region 150 is electrically coupled to the electric-field relaxing region 16. The embedding JTE region 151 is provided outside the embedding region 150, contacts the embedding region 150, and is electrically coupled to the embedding region 150. The embedding guard ring region 152 is provided outside the embedding JTE region 151 to be away from the embedding JTE region 151. The opening 150X is an example of a first opening.

A junction region 160, a JTE region 161, and a guard ring region 162 are provided at the surface of the second region 11B. The junction region 160, the JTE region 161, and the guard ring region 162 include a p-type impurity such as Al, and have p conductivity. The acceptor concentration of the junction region 160 is greater than or equal to 5×10¹⁶ cm⁻³ and less than or equal to 1×10¹⁸ cm⁻³, for example, and the acceptor concentration of the JTE region 161 is greater than or equal to 5×10¹⁶ cm⁻³ and less than or equal to 1×10¹⁸ cm⁻³, for example. The acceptor concentration of the guard ring region 162 is, for example, greater than or equal to 5×10¹⁶ cm⁻³ and less than or equal to 1×10¹⁸ cm⁻³.

Openings 160X are each formed in the junction region 160 so as to overlap a corresponding contact hole 112 when viewed in the plan view from the Z-direction. The second region 11B is exposed through the openings 160X. The junction region 160 is electrically coupled to the contact region 18. The JTE region 161 is provided outside the junction region 160, contacts the junction region 160, and is electrically coupled to the junction region 160. The guard ring region 162 is provided outside the JTE region 161 to be away from the JTE region 161.

The acceptor concentration and the donor concentration in each of the above impurity regions can be measured, for example, by a scanning capacitance microscope (SCM), secondary ion mass spectrometry (SIMS), or the like.

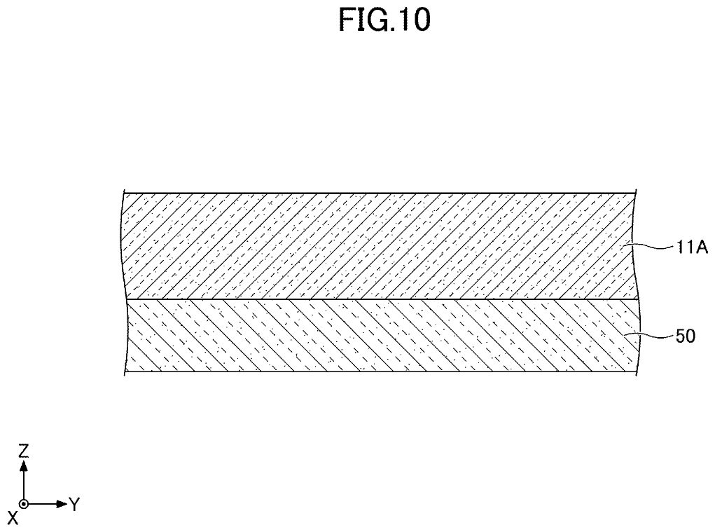

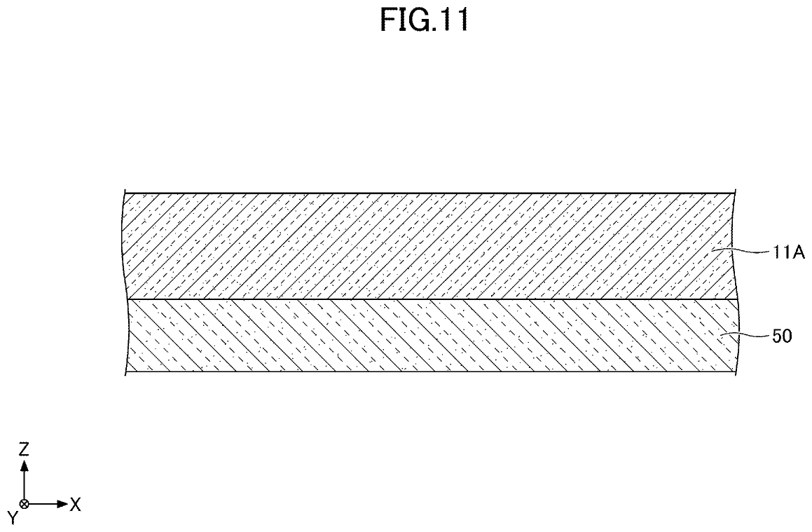

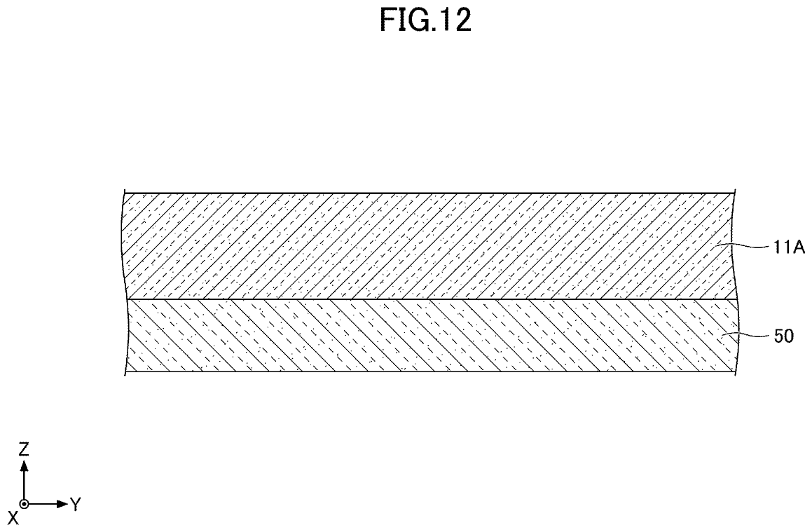

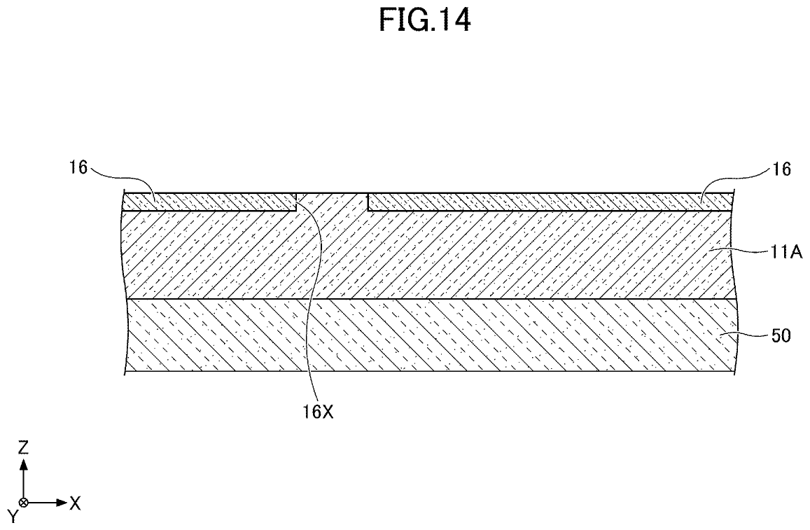

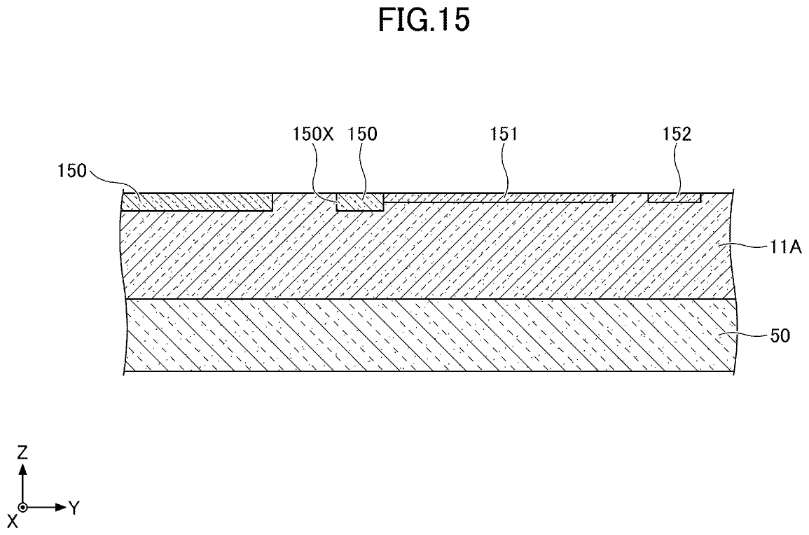

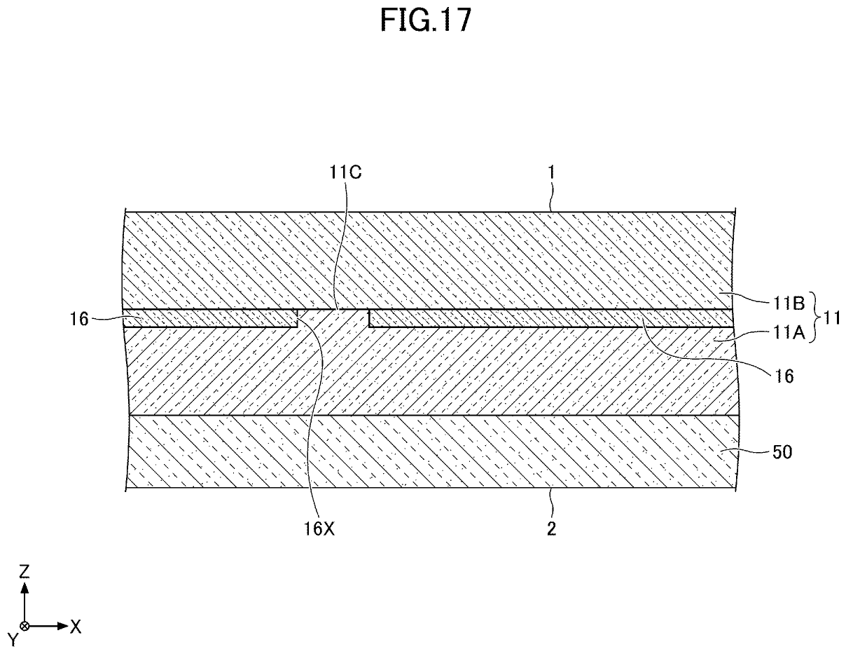

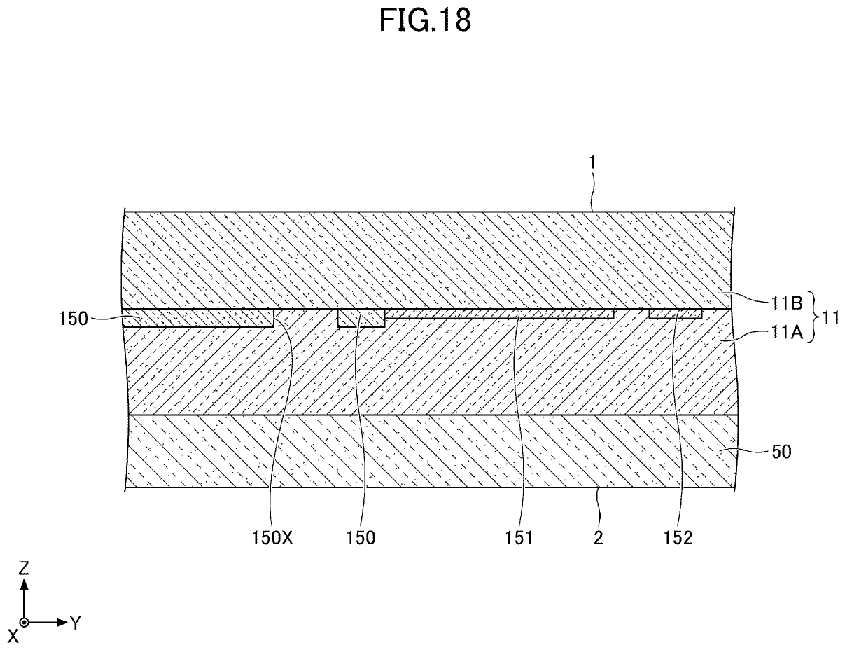

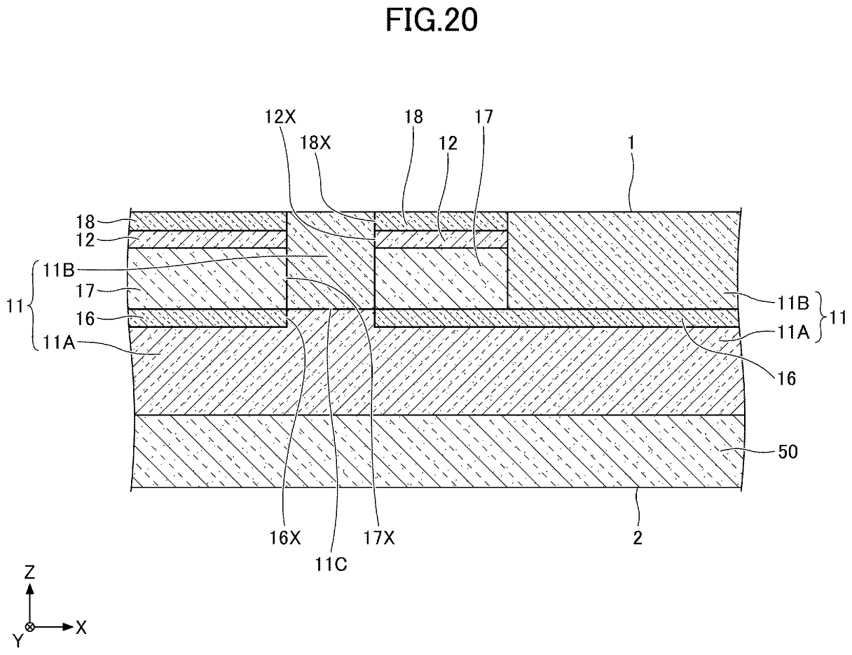

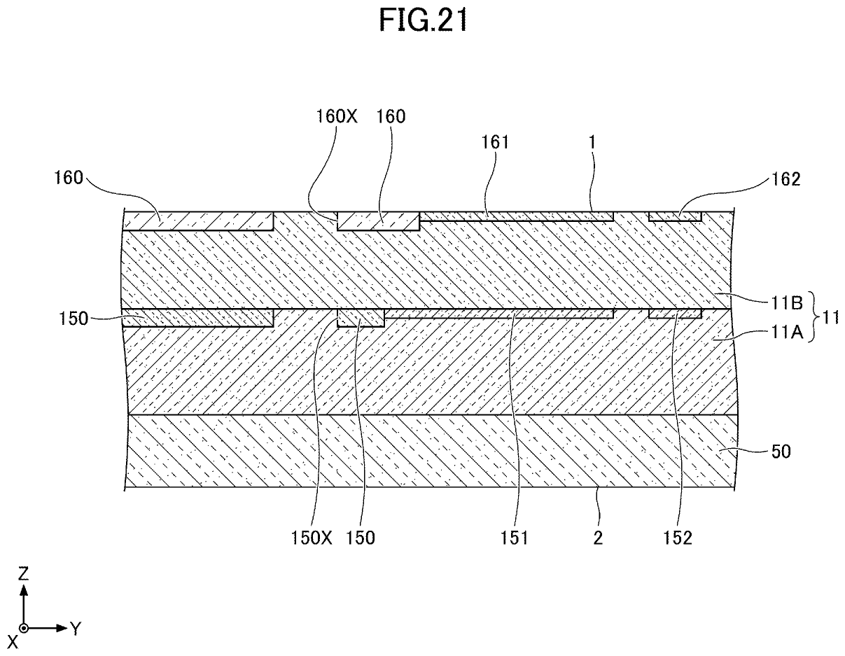

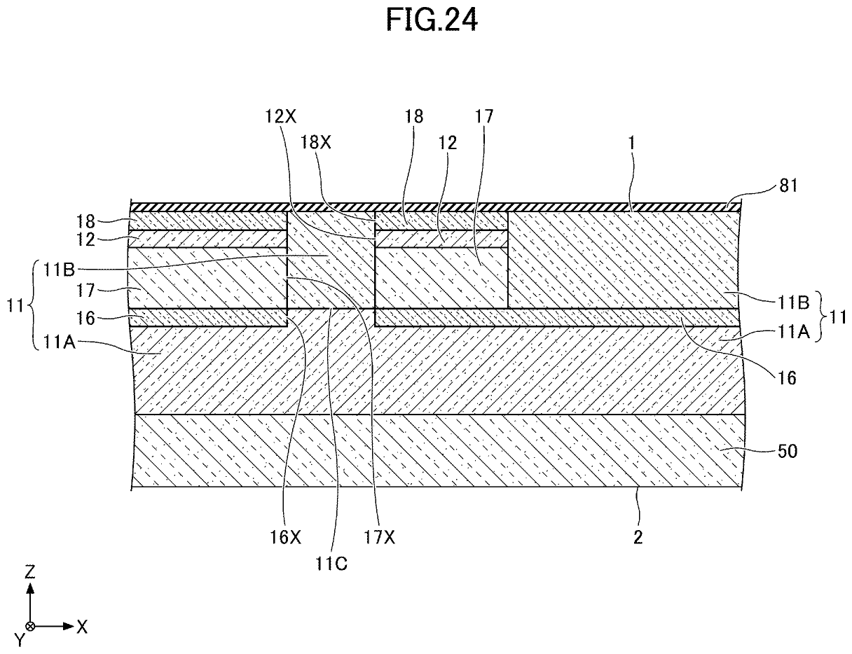

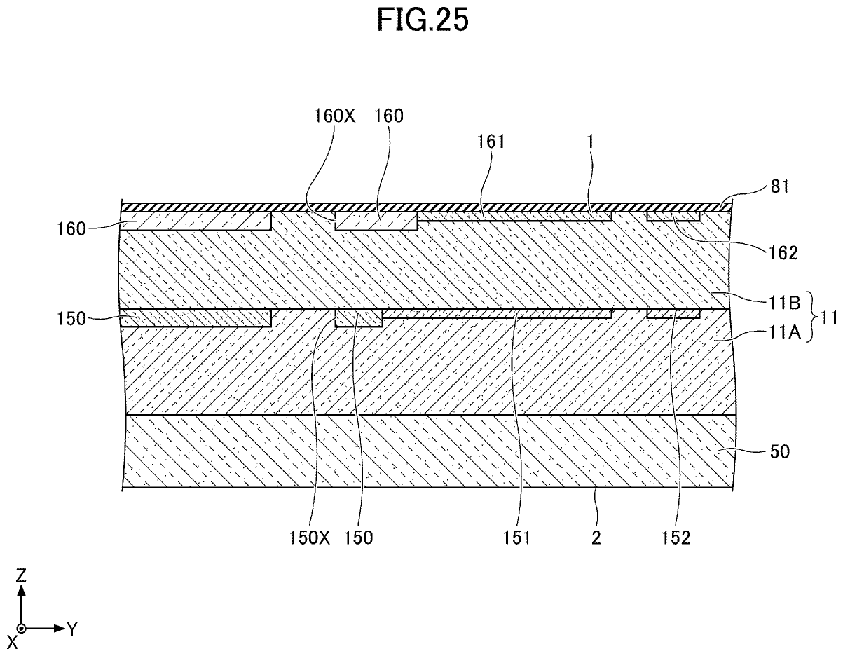

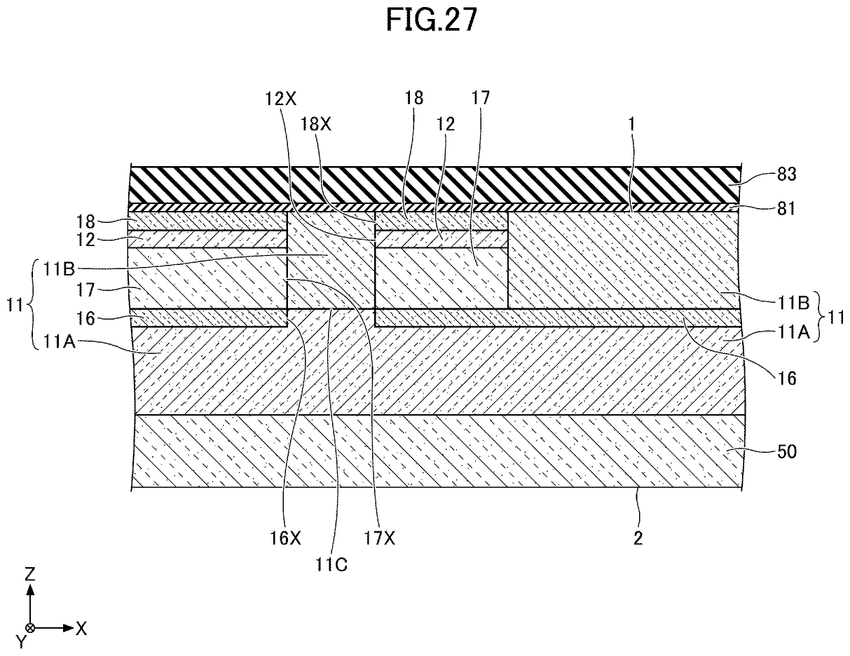

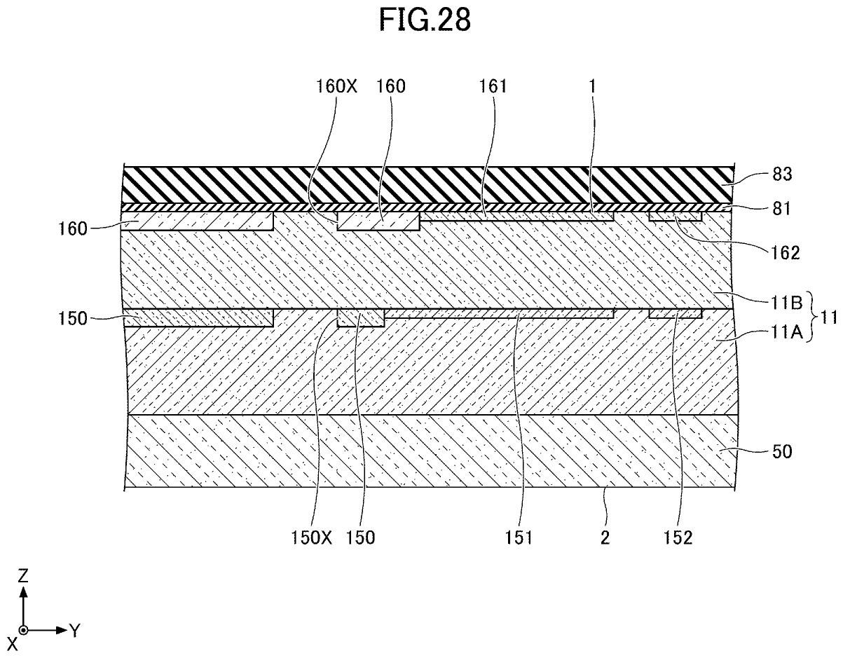

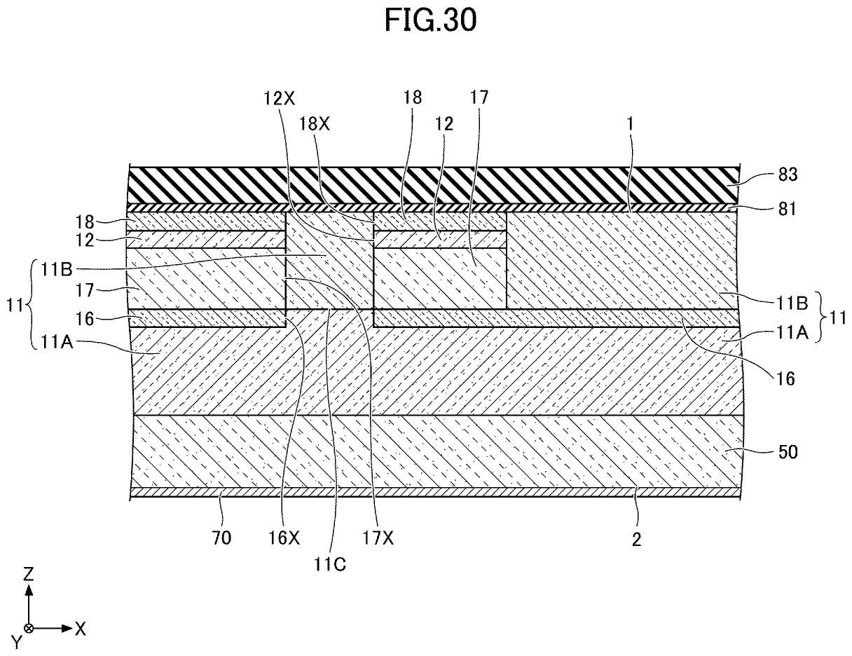

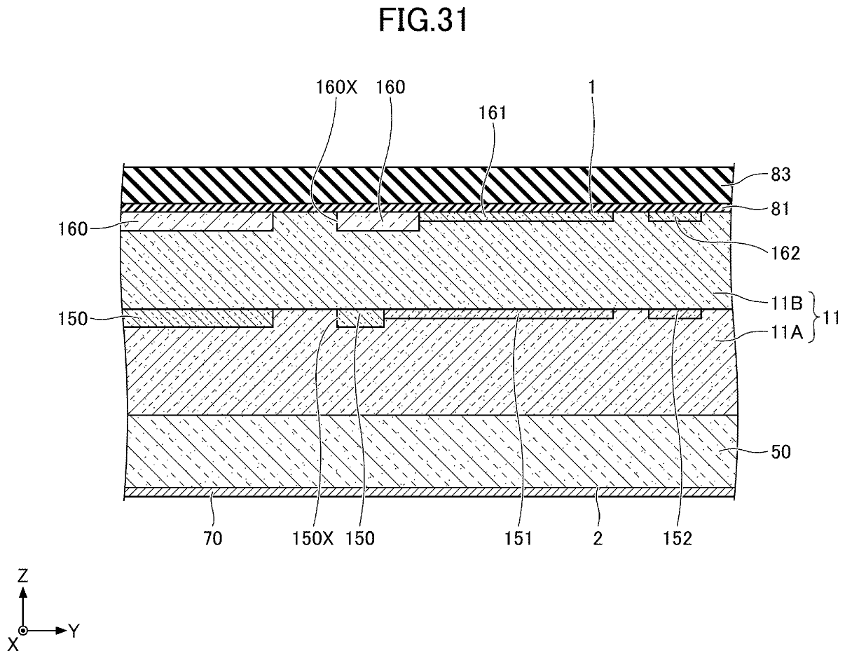

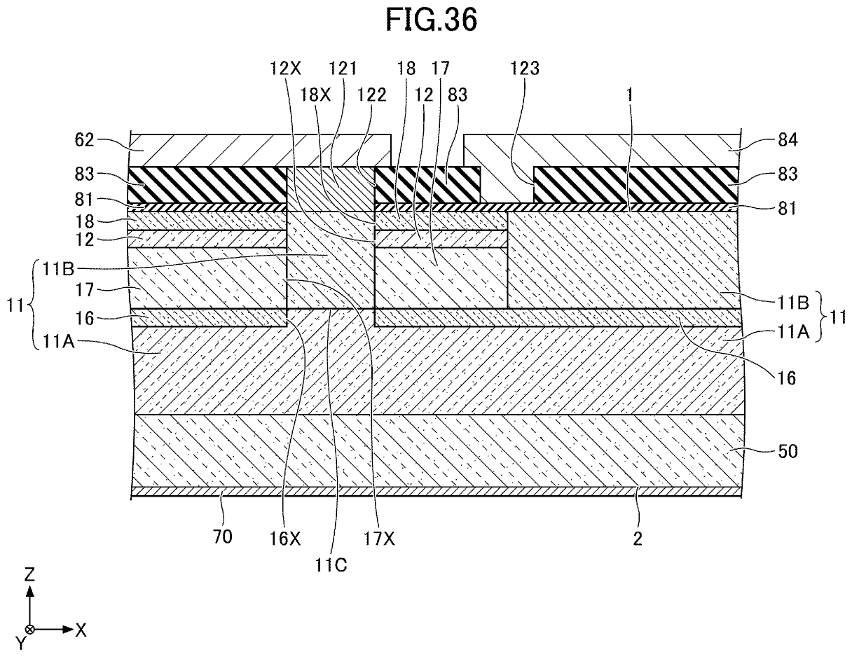

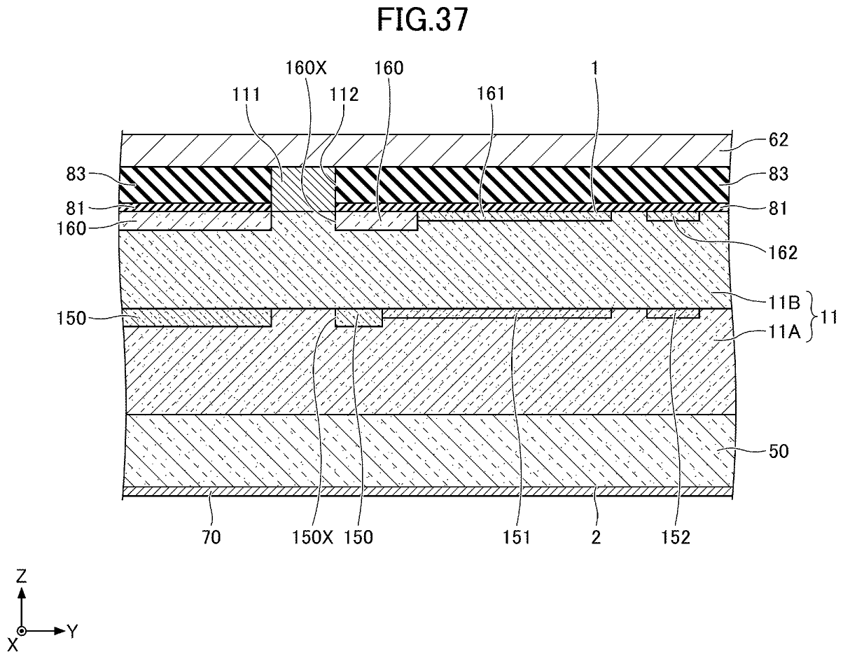

A method for manufacturing the MOSFET 100 according to the embodiment will be described below. FIGS. 10 to 37 are cross-sectional views of the MOSFET 100 according to the embodiment, the views being described for the method for manufacturing the MOSFET 100. FIGS. 10, 13, 16, 19, 22, 23, 26, 29, 32 and 35 illustrate variations of the cross-section illustrated in FIG. 4. FIGS. 11, 14, 17, 20, 24, 27, 30, 33 and 36 illustrate variations of the cross-section illustrated in FIG. 5. FIGS. 12, 15, 18, 21, 25, 28, 31, 34 and 37 illustrate variations of the cross-section illustrated in FIG. 7.

As illustrated in FIGS. 10, 11 and 12, the first region 11A of the drift region 11 is first formed on the silicon carbide single-crystal substrate 50 by epitaxial growth. The epitaxial growth can be used by chemical vapor deposition (CVD) in which a gas mixture of silane (SiH₄) and propane (C₃H₈) is used, for example, as a source gas and, a hydrogenous gas (H₂) is used, for example, as a carrier gas. At this time, for example, nitrogen (N) or phosphorus (P) is preferably introduced as a donor.

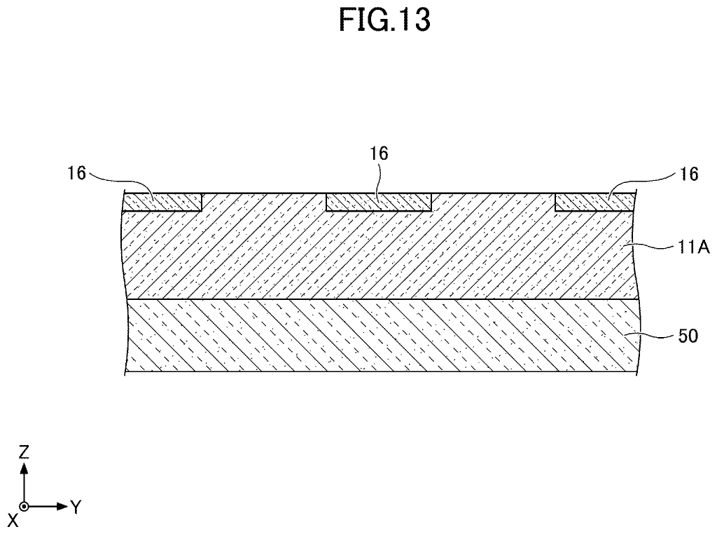

Then, as illustrated in FIGS. 13, 14, and 15, the electric-field relaxing region 16, the embedding region 150, the embedding JTE region 151, and the embedding guard ring region 152 are formed on the surface of the first region 11A. Specifically, ion implantation is performed with respect to the upper surface of the first region 11A. In the ion implantation by which the electric-field relaxing region 16, the embedding region 150, the embedding JTE region 151, and the embedding guard ring region 152 are formed, an acceptor such as aluminum (Al) is implanted with ions.

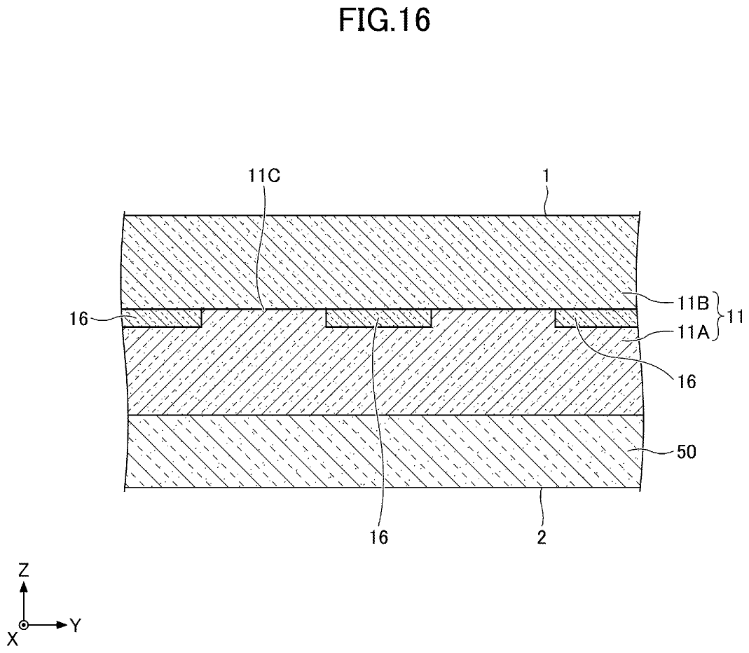

Then, as illustrated in FIGS. 16, 17, and 18, the second region 11B is formed on and above the first region 11A by epitaxial growth. The epitaxial growth can be used by CVD in which a gas mixture of silane (SiH₄) and propane (C₃H₈) is used as a source gas and, a hydrogenous gas (H₂) is used as a carrier gas. At this time, for example, nitrogen (N) or phosphorus (P) is preferably introduced as a donor.

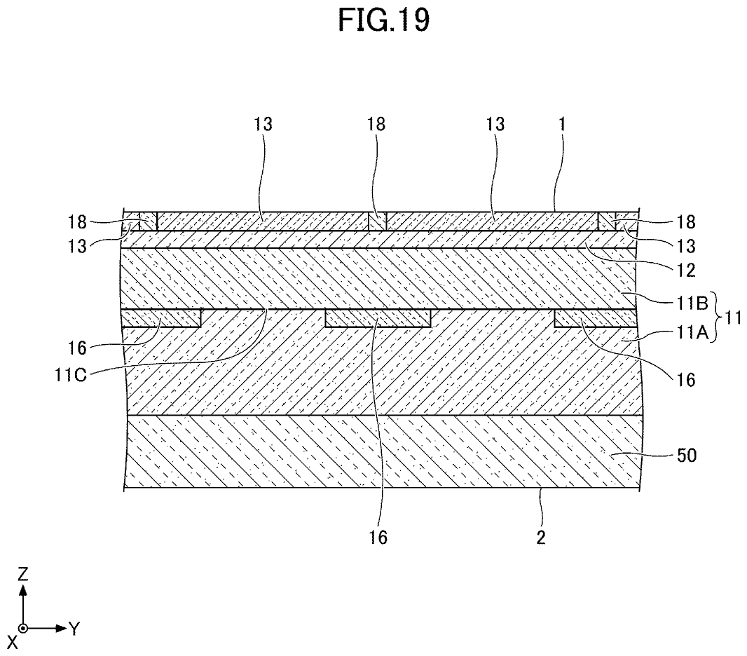

Then, as illustrated in FIGS. 19, 20, and 21, the connection region 17, the body region 12, the source region 13, the contact region 18, the junction region 160, the JTE region 161, and the guard ring region 162 are formed. Specifically, ions are implanted into the upper surface of the drift region 11. In ion implantation with which the connection region 17, the body region 12, the contact region 18, the junction region 160, the JTE region 161, and the guard ring region 162 are formed, an acceptor such as aluminum (Al) is implanted with ions. In ion implantation with which the source region 13 is formed, a donor such as phosphorus (P) is implanted with ions. With this arrangement, the silicon carbide substrate 10 that includes the drift region 11, the body region 12, the source region 13, and the like is formed. Instead of ion implantation, epitaxial growth in which an impurity is added may be used.

Then, activation thermal treatment for activating impurities added by ion implantation is performed. A heat treatment temperature is preferably greater than or equal to 1500° C. and less than or equal to 1900° C., and is, for example, about 1700° C. A time period for heat treatment is, for example, about 30 minutes. The atmosphere of the heat treatment is preferably an inert gas atmosphere, and is, for example, an Ar atmosphere. In such a manner, the silicon carbide substrate 10 is prepared.

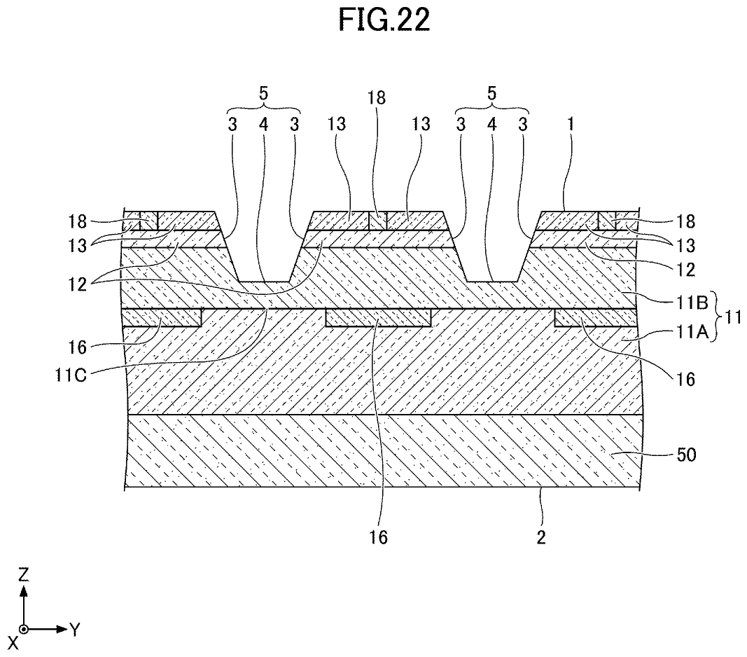

Then, as illustrated in FIG. 22, the gate trenches 5 are formed in the silicon carbide substrate 10. For example, a mask layer (not illustrated) having openings that are each situated at a location where a corresponding gate trench 5 is to be formed is formed on the first main surface 1. With use of the mask layer, a portion of the source region 13, a portion of the body region 12, and a portion of the drift region 11 are removed by etching. As an etching method, for example, reactive ion etching can be used, and particularly, inductively coupled plasma reactive ion etching can be used. Specifically, for example, the inductively coupled plasma reactive ion etching in which sulfur hexafluoride (SF₆) or a gas mixture of SF₆ and oxygen (O₂) is used as a reactive gas can be used. By the etching, each recess (not illustrated), which is defined by: a side portion substantially perpendicular to the first main surface 1; and a bottom portion that is provided continuously with the side portion and is substantially parallel to the first main surface 1, is formed in a region where a corresponding gate trench 5 is to be formed.

Thermal etching is then performed with respect to each recess. The thermal etching may be performed, for example, by adding heat in an atmosphere including a reactive gas that contains at least one kind of halogen atoms, in a state where the mask layer is formed on the first main surface 1. The at least one kind of halogen atom includes at least one of a chlorine (Cl) atom or a fluorine (F) atom. The atmosphere includes, for example, chloride (Cl₂), boron trichloride (BCl₃), SF₆, or tetrafluoromethane (CF₄). For example, a gas mixture of chlorine gas and oxygen gas is used as a reaction gas, and thermal etching is performed, for example, at a thermal treatment temperature of greater than or equal to 800° C. and less than or equal to 900° C. The reaction gas may contain a carrier gas, in addition to the chlorine gas and the oxygen gas as described above.

As the carrier gas, for example, nitrogen gas, argon gas, helium gas, or the like can be used.

By the thermal etching, the gate trenches 5 are formed at the first main surface 1 of the silicon carbide substrate 10. Each gate trench 5 is defined by the side surface 3 and the bottom surface 4. The side surface 3 is formed by the source region 13, the body region 12, and the drift region 11. The bottom surface 4 is formed by the second region 11B of the drift region 11. The mask layer is then removed from the first main surface 1.

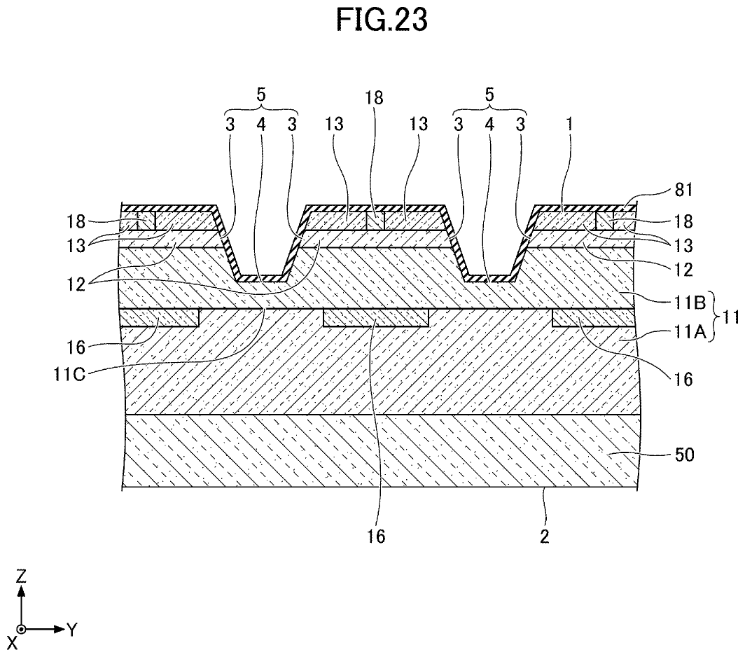

Then, as illustrated in FIGS. 23, 24 and 25, the gate insulating film 81 is formed. For example, the silicon carbide substrate 10 is thermally oxidized to form the gate insulating film 81 that is in contact with the source region 13, the body region 12, the drift region 11, the contact region 18, the second region 11B, the junction region 160, the JTE region 161, and the guard ring region 162. Specifically, the silicon carbide substrate 10 is heated, for example, at a temperature of greater than or equal to 1300° C. and less than or equal to 1400° C., in an atmosphere including oxygen. In such a manner, the gate insulating film 81 that is in contact with the first main surface 1, the side surface 3, and the bottom surface 4 is formed. When the gate insulating film 81 is formed by thermal oxidation, a portion of the silicon carbide substrate 10 is strictly taken into the gate insulating film 81. Thus, in a subsequent process, it is assumed that the first main surface 1, side surfaces 3, and the bottom surfaces 4 have slightly moved to the interface between the gate insulating film 81 and the silicon carbide substrate 10, after thermal oxidation.

Then, heat treatment (annealing by NO) may be performed with the silicon carbide substrate 10 in a nitrogen monoxide (NO) gas atmosphere. In the annealing by NO, the silicon carbide substrate 10 is held for about one hour under a condition of greater than or equal to 1100° C. and less than or equal to than 1400° C., for example. Thus, nitrogen atoms are introduced into an interface region between the gate insulating film 81 and the body region 12. As a result, formation of interface states of the interface region is reduced, and thus channel mobility can be improved.

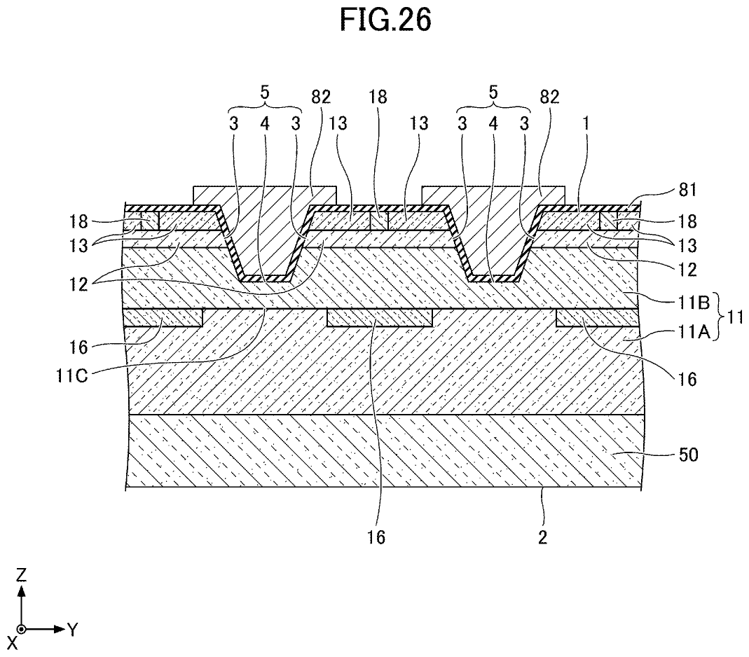

Then, as illustrated in FIGS. 26, 27, and 28, the gate electrodes 82 are formed. The gate electrodes 82 are formed on the gate insulating film 81. The gate electrodes 82 are formed, for example, by low pressure-chemical vapor deposition (LP-CVD). The gate electrodes 82 are each formed to face the source region 13, the body region 12, and the drift region 11.

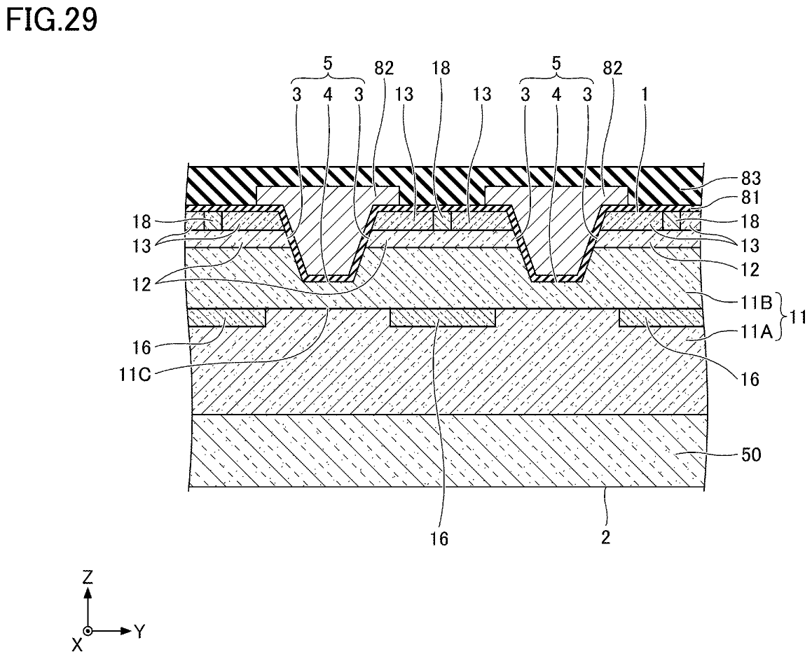

Then, as illustrated in FIGS. 29, 30 and 31, the interlayer insulating film 83 is formed.

Specifically, the interlayer insulating film 83 is formed to cover the gate electrodes 82 and to contact the gate insulating film 81. The interlayer insulating film 83 is formed, for example, by CVD. The interlayer insulating film 83 is made of, for example, a material including silicon dioxide. A portion of the interlayer insulating film 83 may be formed within each gate trench 5.

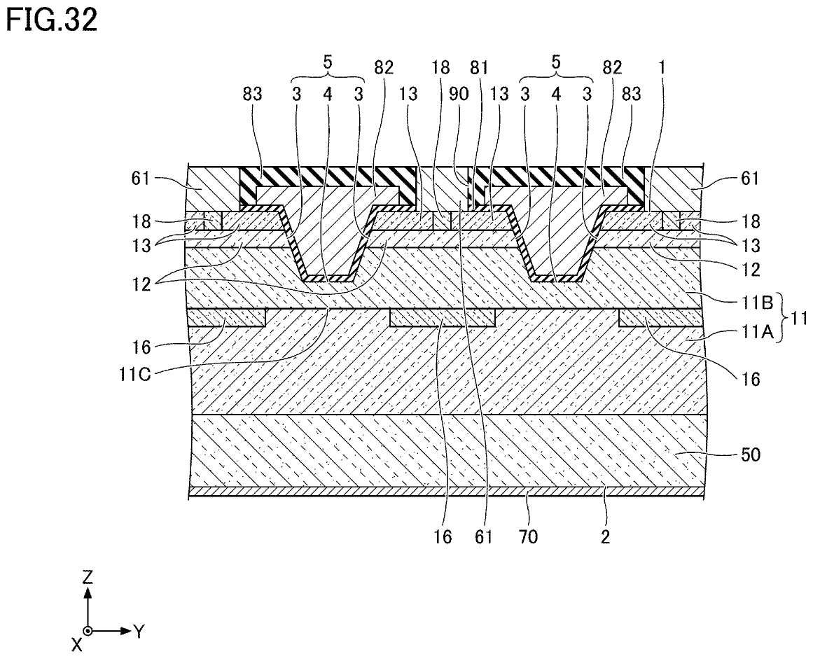

Then, as illustrated in FIG. 32, the interlayer insulating film 83 and the gate insulating film 81 are etched to form the contact hole 90 in the interlayer insulating film 83 and the gate insulating film 81. As a result, each of the source region 13 and the contact region 18 is exposed through the interlayer insulating film 83 and the gate insulating film 81.

Then, a metal film (not illustrated) used for the contact electrode 61, which contacts the source region 13 and the contact region 18 at the first main surface 1, is formed. The metal film used for the contact electrode 61 is formed, for example, by sputtering. The metal film used for the contact electrode 61 is made of, for example, a material including Ni. Next, a metal film (not illustrated) used for the drain electrode 70, which contacts the silicon carbide single-crystal substrate 50 at the second main surface 2, is formed. The metal film used for the drain electrode 70 is formed, for example, by sputtering. The metal film used for the drain electrode 70 is made of, for example, a material including Ni.

Then, annealing in which an alloy is formed is performed. The metal film used for the contact electrode 61 and the metal film used for the drain electrode 70 are held, for example, at a temperature of greater than or equal to 900° C. and less than or equal to 1100° C., for about 5 minutes. With this arrangement, at least a portion of the metal film used for the contact electrode 61 and at least a portion of the metal film used for the drain electrode 70 react with silicon included in the silicon carbide substrate 10, and thus silicidation is enabled. Thus, the contact electrode 61 that is in ohmic contact with the source region 13 and the contact region 18, as well as the drain electrode 70 that is in ohmic contact with the silicon carbide single-crystal substrate 50, are formed. The contact electrode 61 may be made of a material including Ti, Al, and Si. The drain electrode 70 may be made of a material including Ti, Al, and Si.

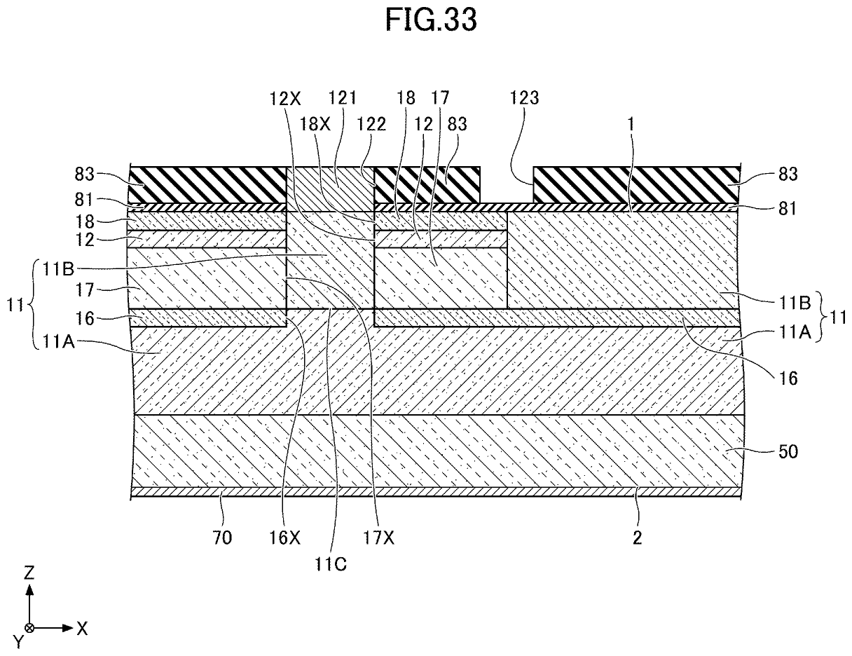

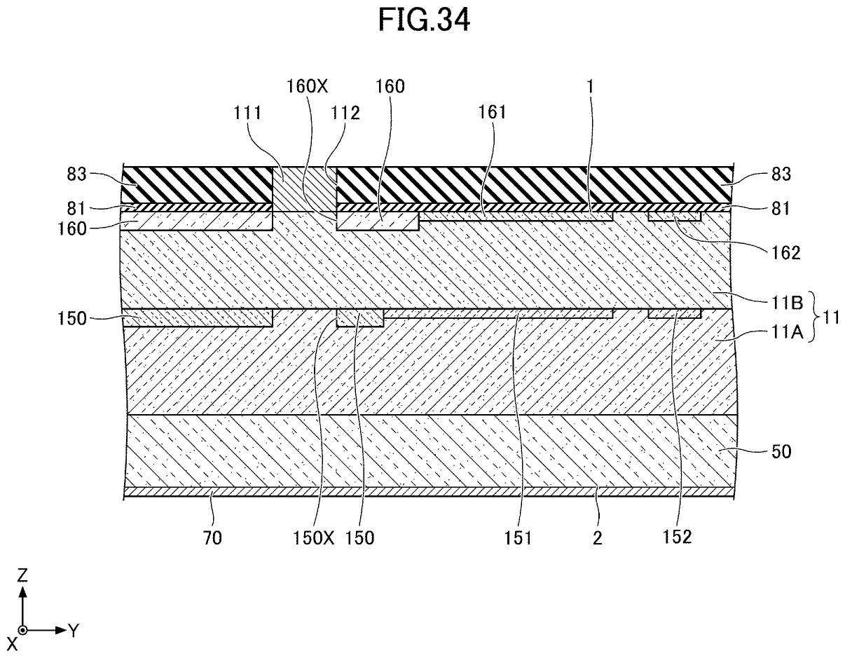

Then, as illustrated in FIGS. 33 and 34, the interlayer insulating film 83 and the gate insulating film 81 are etched to form contact holes 112 and 122 that are each in the interlayer insulating film 83 and the gate insulating film 81. As a result, the second region 11B is exposed through the interlayer insulating film 83 and the gate insulating film 81.

Then, Schottky electrodes 111 and 121 are formed to contact the second region 11B at the first main surface 1. The Schottky electrodes 111 and 121 are formed, for example, by sputtering. The Schottky electrodes 111 and 121 are made of a material including, for example, Hf, Zr, Ta, Mn, Nb, and V.

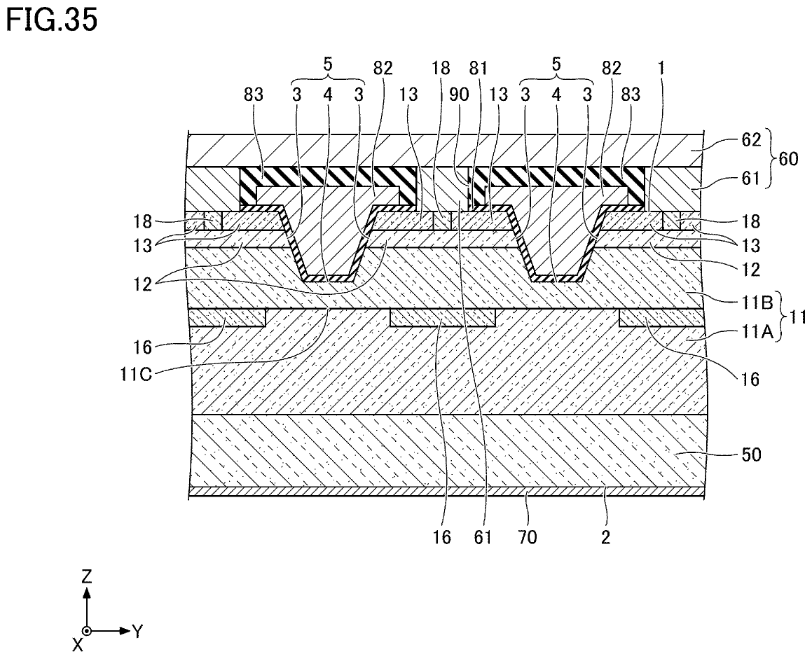

Then, as illustrated in FIGS. 35, 36, and 37, the interlayer insulating film 83 and the gate insulating film 81 are etched to form the contact hole 123 in the interlayer insulating film 83 and the gate insulating film 81. As a result, the gate electrode 82 is exposed through the interlayer insulating film 83 and the gate insulating film 81. Next, the source line 62, the gate pad 84, and the gate runners 85 are formed. The source line 62, the gate pad 84, and the gate runners 85 are formed by deposition by sputtering and RIE, for example. The source line 62, the gate pad 84, and the gate runners 85 are made of a material including, for example, aluminum. The source electrode 60 that includes the contact electrode 61 and the source line 62 is formed.

In such a manner, the MOSFET 100 according to the embodiment is completed.

In the MOSFET 100 according to the present embodiment, the Schottky electrodes 111 are each provided so as to overlap a corresponding opening 150X that is formed in the embedding region 150, when viewed in the plan view from the Z-direction. With this arrangement, when the first Schottky barrier diode 22 operates, the current flows toward the drain electrode 70 through the corresponding opening 150X. If any opening 150X is not formed, the current flows so as to bypass the embedding region 150. In contrast, if the openings 150X are formed, a current path can be shortened. Reductions in the resistance of the current path make it easier for the first Schottky barrier diode 22 to start up. With this arrangement, the first Schottky barrier diode 22 operates more quickly than a diode with a parasitic p-n junction in the MOSFET 100, and thus reductions in the property in accordance with the operation of the p-n junction diode can be mitigated.

When viewed in the plan view from the Z-direction, the distance L1 between electric-field relaxing regions 16 that are adjacent to each other in the active region 120A is greater than the length L2 of the shortest side of the opening 150X, and thus electric field concentration of the embedding region 150 is reduced. Therefore, reductions in the withstanding voltage of the terminal region 110 can be mitigated.

The second Schottky barrier diodes 23 are provided in the non-active region 120B, and the Schottky electrodes 121 of the second Schottky barrier diodes 23 are each provided so as to overlap a corresponding opening 16X that is formed in the electric-field relaxing region 16, when viewed in the plan view from the Z-direction. With this arrangement, reductions in the property in accordance with the operation of the p-n junction diode in the non-active region 120B can be mitigated.

The second Schottky barrier diodes 23 are arranged along the gate pad 84, when viewed in the plan view from the Z-direction, and thus reductions in the property in accordance with the operation of the p-n junction diode that includes the electric-field relaxing region 16 below the gate pad 84 can be mitigated. In addition, the second Schottky barrier diodes 23 are arranged along the gate runner 85 when viewed in the plan view from the Z-direction, and thus reductions in the property in accordance with the operation of the p-n junction diode that includes the electric-field relaxing region 16 below the gate runner 85 can be mitigated.

A turn-on voltage of the second Schottky barrier diode 23 is preferably lower than a turn-on voltage of a diode with the p-n junction between a portion of the electric-field relaxing region 16 in the non-active region 120E and the drift region 11. This is because reductions in the property in accordance with the operation of the diode with the p-n junction are mitigated.

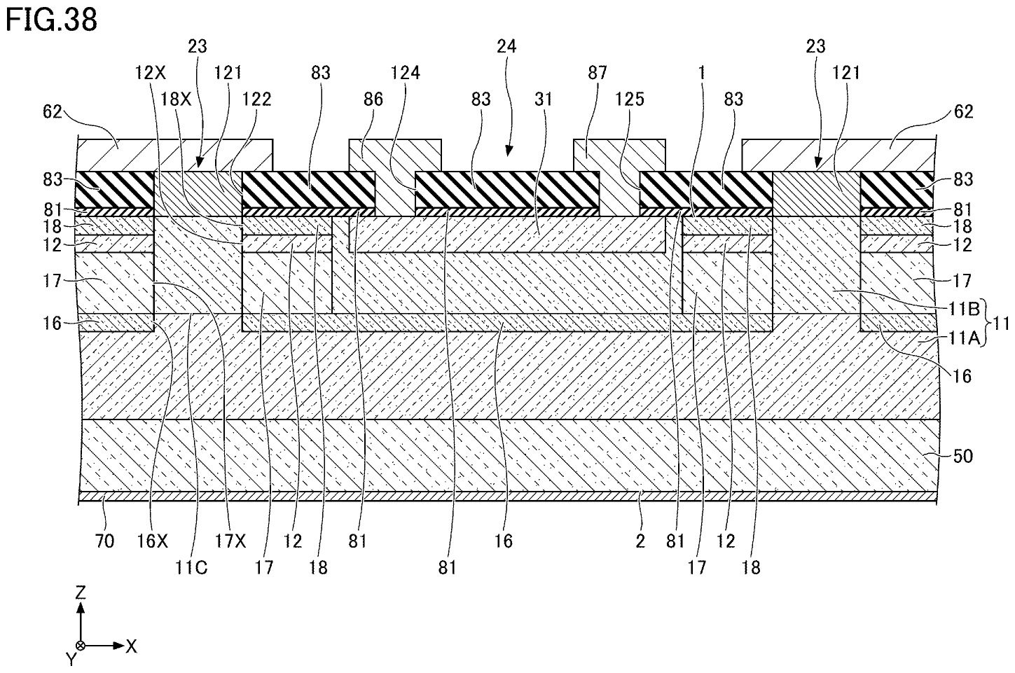

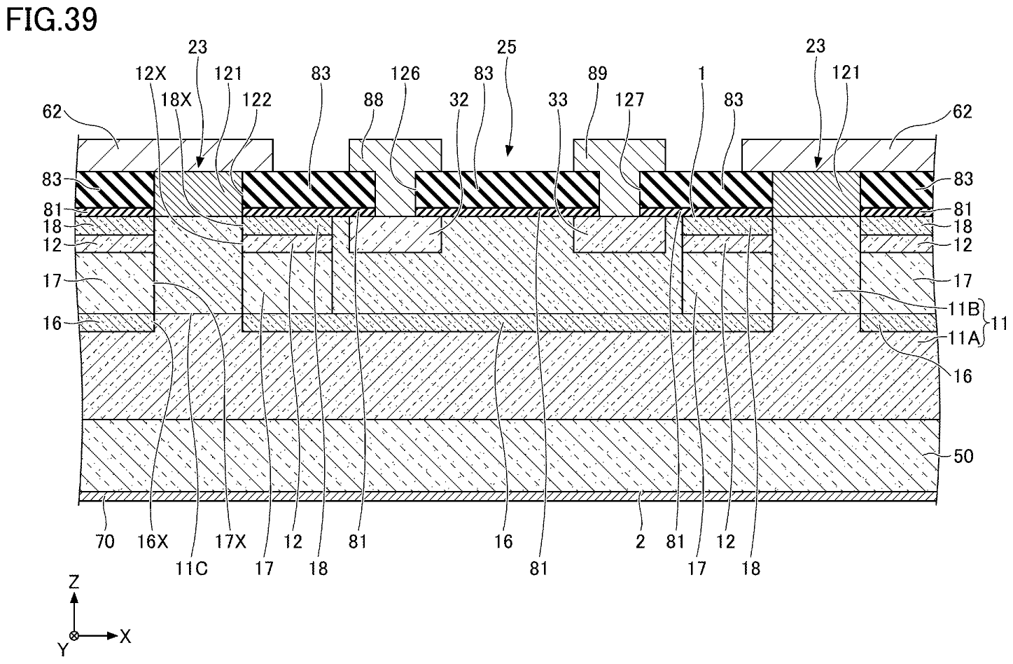

A temperature sensing structure may be provided in the non-active region 120B, and in this case, the second Schottky barrier diodes 23 may be arranged along the temperature sensing structure when viewed in the plan view from the Z-direction. FIG. 38 is a cross-sectional view of an example of the silicon carbide semiconductor device having the temperature sensing structure. FIG. 39 is a cross-sectional view illustrating another example of the silicon carbide semiconductor device having the temperature sensing structure.

In the example illustrated in FIG. 38, the second

Schottky barrier diodes 23 are disposed along a temperature sensing structure 24. The temperature sensing structure 24 includes an n-type region 31 that is formed at the surface of the second region 11B. The n-type region 31 is the n-type by being doped with a donor such as nitrogen or phosphorus. The n-type region 31 forms the first main surface 1. A donor concentration of the n-type region 31 is greater than or equal to 1×10¹⁸ cm³ and less than or equal to 1×10²⁰ cm⁻³, for example. Contact holes 124 and 125 through which the n-type region 31 is exposed are each formed in the interlayer insulating film 83 and the gate insulating film 81. The temperature sensing structure 24 includes a terminal 86 that is in ohmic contact with the n-type region 31 through the contact hole 124, and includes a terminal 87 that is in ohmic contact with the n-type region 31 through the contact hole 125. In the temperature sensing structure 24, the temperature of the silicon carbide semiconductor device can be measured by measuring, through the terminals 86 and 87, the electrical resistance, of the n-type region 31, that varies with temperature.

In the example illustrated in FIG. 39, the second Schottky barrier diodes 23 are disposed along a temperature sensing structure 25. The temperature sensing structure 25 includes a p-type region 32 and an n-type region 33 that are formed on the surface of the second region 11B. The p-type region 32 is the p-type by being doped with an acceptor such as aluminum. The p-type region 32 forms the first main surface 1. An acceptor concentration of the p-type region 32 is greater than or equal to 1×10¹⁸ cm⁻³ and less than or equal to 1×10²⁰ cm⁻³, for example. The n-type region 33 is the n-type by being doped with a donor such as nitrogen or phosphorus. The N-type region 33 forms the first main surface 1. A donor concentration of the n-type region 33 is greater than or equal to 1×10¹³ cm⁻³ and less than or equal to 1×10²⁰ cm⁻³, for example. A contact hole 126 through which the p-type region 32 is exposed, as well as a contact hole 127 through which the n-type region 33 is exposed, are each formed in the interlayer insulating film 83 and the gate insulating film 81. The temperature sensing structure 25 has a terminal 88 that is in ohmic contact with the p-type region 32 through the contact hole 126, and includes a terminal 89 that is in ohmic contact with the n-type region 33 through the contact hole 127. In the temperature sensing structure 25, the temperature of the silicon carbide semiconductor device can be measured by measuring, through terminals 88 and 89, the electrical resistance of the diode that includes the p-type region 32 and the n-type region 33, the electrical resistance varying with temperature.

The second Schottky barrier diodes 23 are arranged along the temperature sensing structures 24 and 25 when viewed in the plan view from the Z-direction, and thus reductions in the property in accordance with the operation of the p-n junction diode that includes the electric-field relaxing region 16 below the temperature sensing structures 24 and 25 can be mitigated.

Although the embodiments are described in detail above, the embodiments are not limited to a specific embodiment, and various modifications and changes can be made within the scope set forth in the claims.

### Description of Symbols

1 first main surface
2 second main surface
3 side surface
4 bottom surface
5 gate trench
10 silicon carbide substrate
11 drift region (which is an example of a first
15 semiconductor region)
11A first region
11B second region
11C first surface
12 body region
12X, 16X, 17X, 18X, 150X, 160X opening
13 source region
16 electric-field relaxing region (which is a portion of a second semiconductor region)
17 connection region
18 contact region
21 transistor
22 first Schottky barrier diode
23 second Schottky barrier diode
24, 25 temperature sensing structure
30 31, 33 n-type region
32 p-type region
40 silicon carbide epitaxial layer
50 silicon carbide-single crystal substrate
60 source electrode
61 contact electrode
62 source line
70 drain electrode
81 gate insulating film
82 gate electrode
83 interlayer insulating film
84 gate pad
85 gate runner
86, 87, 88, 89 terminal
90 contact hole
100 MOSFET
110 termination region
111 Schottky electrode
112 contact hole
120 element region
120A active region
120B non-active region
121 Schottky electrode
122, 123, 124, 125, 126, 127 contact hole
150 embedding region (which is a portion of a second semiconductor region)
151 embedding JTE region
152 embedding guard ring region
160 junction region
161 JTE region
162 guard ring region
A, B region

1. A silicon carbide semiconductor device comprising:
a silicon carbide substrate having a first main surface and a second main surface opposite the first main surface,
wherein, when viewed in a plan view from a direction perpendicular to the first main surface, the silicon carbide substrate includes
an element region including a plurality of transistors, and
a termination region surrounding the element region, the termination region including a first Schottky barrier diode,
wherein the silicon carbide substrate forms the second main surface, the silicon carbide substrate including
a first semiconductor region having a first conductivity type,
a first surface located between the first main surface and the second main surface, and
a second semiconductor region provided on the first surface, the second semiconductor region having a second conductivity type different from the first conductivity type,
wherein the second semiconductor region includes a first embedding region provided in the termination region, a first opening being formed in the first embedding region, and
wherein the first Schottky barrier diode includes a first Schottky electrode provided on the first main surface, the first Schottky electrode overlapping the first opening when viewed in the plan view from the direction perpendicular to the first main surface.

2. The silicon carbide semiconductor device according to claim 1, wherein the first opening has a rectangular planar shape,
wherein the second semiconductor region includes a plurality of electric-field relaxing regions provided in the element region, and
wherein a distance between adjacent electric-field relaxing regions is greater than a length of a shortest side of the first opening, when viewed in the plan view from the direction perpendicular to the first main surface.

3. The silicon carbide semiconductor device according to claim 1, wherein the element region includes
an active region in which the plurality of transistors are arranged, and
a non-active region provided around the active region, the non-active region including a plurality of second Schottky barrier diodes,
wherein the second semiconductor region includes a second embedding region provided in the non-active region, a second opening being formed in the second embedding region, and
wherein each of the second Schottky barrier diodes includes a second Schottky electrode provided on the first main surface, the second Schottky electrode overlapping the second opening when viewed in the plan view from the direction perpendicular to the first main surface.

4. The silicon carbide semiconductor device according to claim 3, further comprising:
a gate pad to which gate electrodes of the plurality of transistors are coupled, the gate pad being situated above the first main surface,
wherein a plurality of the second Schottky barrier diodes are arranged along the gate pad when viewed in the plan view from the direction perpendicular to the first main surface.

5. The silicon carbide semiconductor device according to claim 3, further comprising:
a gate runner to which the gate electrodes of the plurality of transistors are coupled, the gate runner being situated above the first main surface,
wherein a plurality of the second Schottky barrier diodes are arranged along the gate runner when viewed in the plan view from the direction perpendicular to the first main surface.

6. The silicon carbide semiconductor device according to claim 3, further comprising:
a temperature sensing structure provided in the non-active region, wherein a plurality of the second Schottky barrier diodes are arranged along the temperature sensing structure when viewed in the plan view from the direction perpendicular to the first main surface.

7. The silicon carbide semiconductor device according to claim 3, wherein a turn-on voltage of each of the plurality of second Schottky barrier diodes is lower than a turn-on voltage of a diode that includes a p-n junction between the second embedding region and the first semiconductor region.

8. The silicon carbide semiconductor device according to claim 2, wherein the element region includes
an active region in which the plurality of transistors are arranged, and
a non-active region provided around the active region, the non-active region including a plurality of second Schottky barrier diodes,
wherein the second semiconductor region includes a second embedding region provided in the non-active region, a second opening being formed in the second embedding region, and
wherein each of the second Schottky barrier diodes includes a second Schottky electrode provided on the first main surface, the second Schottky electrode overlapping the second opening when viewed in the plan view from the direction perpendicular to the first main surface.

9. The silicon carbide semiconductor device according to claim 4, further comprising:
a gate runner to which the gate electrodes of the plurality of transistors are coupled, the gate runner being situated above the first main surface,
wherein a plurality of the second Schottky barrier diodes are arranged along the gate runner when viewed in the plan view from the direction perpendicular to the first main surface.

10. The silicon carbide semiconductor device according to claim 4, further comprising:
a temperature sensing structure provided in the non-active region,
wherein a plurality of the second Schottky barrier diodes are arranged along the temperature sensing structure when viewed in the plan view from the direction perpendicular to the first main surface.

11. The silicon carbide semiconductor device according to claim 5, further comprising:
a temperature sensing structure provided in the non-active region,
wherein a plurality of the second Schottky harrier diodes are arranged along the temperature sensing structure when viewed in the plan view from the direction perpendicular to the first main surface.

12. The silicon carbide semiconductor device according to claim 4, wherein a turn-on voltage of each of the plurality of second Schottky barrier diodes is lower than a turn-on voltage of a diode that includes a p-n junction between the second embedding region and the first semiconductor region.

13. The silicon carbide semiconductor device according to claim 5, wherein a turn-on voltage of each of the plurality of second Schottky barrier diodes is lower than a turn-on voltage of a diode that includes a p-n junction between the second embedding region and the first semiconductor region.
